(19) United States
(12) Patent Application Publication
(10) Pub. No.: US 2025/0221150 A1
(43) Pub. Date: Jul. 3, 2025

(54) LIGHT-EMITTING DEVICE AND LIGHT-EMITTING DISPLAY DEVICE INCLUDING THE SAME

(71) Applicant: LG Display Co., Ltd., Seoul (KR)

(72) Inventors: Yu Jeong LEE, Paju-si (KR); Chun Ki KIM, Paju-si (KR); Eun Jung PARK, Paju-si (KR); Jun Su HA, Paju-si (KR)

(73) Assignee: LG Display Co., Ltd., Seoul (KR)

(21) Appl. No.: 19/004,108

(22) Filed: Dec. 27, 2024

(30) Foreign Application Priority Data
Dec. 29, 2023 (KR) 10-2023-0197884

(51) Int. Cl. H10K 50/12; H10K 50/16; H10K 50/18; H10K 59/123; H10K 101/00; H10K 101/10; H10K 101/40; H10K 102/00

(52) U.S. Cl. CPC H10K 50/12; H10K 50/16; H10K 50/181; H10K 59/123; H10K 2101/10; H10K 2101/27; H10K 2101/40; H10K 2102/351

(57) ABSTRACT

A light-emitting device can include a first electrode and a second electrode facing each other, and an electron blocking layer, a light emitting layer, and an electron transport layer provided between the first electrode and the second electrode, and an energy transfer layer provided between the electron blocking layer and the light emitting layer. The light emitting layer can include a host and a dopant, and a triplet energy level of the energy transfer layer is higher than a triplet energy level of the host and is lower than a singlet energy level of the host. The light-emitting device can include an energy transfer layer to improve delayed light emission efficiency by generating TTF in the light-emitting layer, and also improves lifespan using excitons in the light-emitting layer. The light-emitting diode can be a display device or a lighting device.

### CROSS-REFERENCE TO RELATED APPLICATION

This application claims priority under 35 U.S.C. § 119(a) to Korean Patent Application No. 10-2023-0197884, filed in the Republic of Korea on Dec. 29, 2023, the entire contents of which is hereby incorporated by reference in its entirety into the present application.

### BACKGROUND

### Technical Field

The disclosure relates to a light-emitting device having a structure modified to improve luminous efficacy as well as lifespan and a light-emitting display device including the same.

### Discussion of the Related Art

With the advent of the information society, displays for visually expressing electrical information signals have rapidly developed. In response to this, a variety of display devices with excellent performance such as slimness, low weight, and low power consumption are being developed.

Among these devices, a light-emitting display device that does not require a separate light source to realize compactness and clear color and has a light-emitting device in a display panel has been considered as a competitive application.

The light-emitting device can include an anode and a cathode facing each other as electrodes, a light-emitting layer between the anode and the cathode, and a common layer for transferring holes and electrons to the light-emitting layer.

Meanwhile, light-emitting devices use light-emitting materials that emit light with different wavelengths for expressing color, and can have differences in efficiency and lifespan of the light-emitting materials depending on wavelength.

### SUMMARY OF THE DISCLOSURE

Accordingly, the disclosure is directed to a light-emitting device and a light-emitting display device that substantially obviate one or more problems due to the limitations and disadvantages of the related art.

It is an object of the present disclosure to provide a light-emitting device that maintains the balance of holes and electrons in a light-emitting layer without changing over time, to prevent excitons or electrons from accumulating at the interface of adjacent layers of the light-emitting layer, and improve efficiency and lifespan of the light-emitting layer through energy transfer from the adjacent layer of the light-emitting layer into the light-emitting layer.

Additional advantages, objects, and features of the disclosure will be set forth in part in the description which follows and in part will become apparent to those having ordinary skill in the art upon examination of the following, or can be learned from practice of the disclosure. The objectives and other advantages of the disclosure can be realized and attained by the structure particularly pointed out in the written description and claims hereof as well as the appended drawings.

A light-emitting device according to some embodiments of the present disclosure includes a first electrode and a second electrode facing each other, and an electron blocking layer, a light emitting layer, and an electron transport layer provided between the first electrode and the second electrode, and an energy transfer layer provided between the electron blocking layer and the light emitting layer, wherein the light emitting layer includes a host and a dopant, and a triplet energy level of the energy transfer layer is higher than a triplet energy level of the host and is lower than a singlet energy level of the host.

It is to be understood that both the foregoing general description and the following detailed description of the disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate some embodiments of the disclosure and together with the description serve to explain the principle of the disclosure. In the drawings:

FIG. 1 is a sectional view illustrating a configuration of a light-emitting device according to some embodiments of the present disclosure;

FIG. 2 shows an energy band diagram of each layer adjacent to an intermediate layer of the light-emitting device of the present disclosure;

FIG. 3 is a diagram showing charge distribution in the intermediate layer of the light-emitting device of the present disclosure;

FIG. 4 shows the structure of Experimental Examples 1 to 5 used in Experiment 1;

FIG. 5A shows the delayed fluorescence emission mechanism of Experimental Example 1;

FIG. 5B shows the delayed fluorescence emission mechanism of Experimental Example 2;

FIG. 5C shows the delayed fluorescence emission mechanism of Experimental Example 3;

FIG. 5D shows the delayed fluorescence emission mechanism of Experimental Examples 4 and 5;

FIG. 6A is a cross-sectional view illustrating the HOD used in Experiment 3;

FIG. 6B is a graph showing IV characteristics for each material used in the HOD of FIG. 6A;

FIG. 7A is a cross-sectional view illustrating the HOD used in Experiment 4;

FIG. 7B is a graph showing IV characteristics for each material used in the EOD of FIG. 7A;

FIGS. 8A to 8C are cross-sectional views illustrating a light-emitting device according to some embodiments of the present disclosure;

FIG. 9 is a cross-sectional view illustrating the light-emitting device used in Experiment5;

FIG. 10 is a cross-sectional view illustrating the light-emitting device used in Experiment 6; and

FIG. 11 is a cross-sectional view illustrating the light-emitting display device according to some embodiments.

### DETAILED DESCRIPTION OF THE EMBODIMENTS

Reference will now be made in detail to some embodiments of the present disclosure, examples of which are illustrated in the accompanying drawings. Wherever possible, the same reference numbers will be used throughout the drawings to refer to the same or like parts, unless otherwise specified.

Advantages and features of the present disclosure, and a method of achieving the advantages and features will become apparent with reference to some embodiments described herein in detail together with the accompanying drawings. The present disclosure should not be construed as limited to the example embodiments as disclosed below, and can be embodied in various different forms. Thus, these example embodiments are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations can unnecessarily obscure an important point of the present disclosure, a detailed description of such steps, elements, functions, technologies, and configurations can be omitted. In addition, the names of elements used in the following description are selected in consideration of clarity of description of the specification, and can differ from the names of elements of actual products. Furthermore, in the following detailed description of the present disclosure, numerous specific details are set forth in order to provide a sufficiently thorough understanding of the present disclosure. However, it will be understood that the present disclosure can be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example embodiments of the present disclosure are merely given by way of example. The disclosure is not limited to the illustrations in the drawings. Further, the term “can” fully encompasses all the meanings and coverages of the term “may.”

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first clement, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

In the following description of the present disclosure, the Lowest Unoccupied Molecular Orbital (LUMO) energy level and the Highest Occupied Molecular Orbital (HOMO) energy level of a layer mean the LUMO energy level and the HOMO energy level of a material constituting a major weight ratio of the corresponding layer, unless they refer to the LUMO energy level and the HOMO energy level of a dopant material doping the corresponding layer.

In the present disclosure, the HOMO energy level and the LUMO energy level are measured values below the vacuum level of 0 eV, thus they are negative values. When the HOMO energy levels or LUMO energy levels of materials are compared, that the HOMO energy level (or the LUMO energy level) of a first material is larger than the HOMO energy level (or the LUMO energy level) of a second material in an energy band diagram means that the HOMO energy level (or the LUMO energy level) of the second material is larger than the HOMO energy level (or the LUMO energy level) of the first material in absolute values. When the HOMO energy levels or LUMO energy levels of materials are compared, that the HOMO energy level (or the LUMO energy level) of a first material is lower than the HOMO energy level (or the LUMO energy level) of a second material in an energy band diagram means that the HOMO energy level (or the LUMO energy level) of the first material is larger than the HOMO energy level (or the LUMO energy level) of the second material in an absolute value.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, an electron transport layer.

Hereinafter, example embodiments of the present disclosure will be described in detail with reference to the accompanying drawings. All the components of the inorganic light emitting display device according to all embodiments of the present disclosure are operatively coupled and configured.

In adding reference numerals to elements of each of the drawings, although the same elements are illustrated in other drawings, like reference numerals can refer to like elements. Further, for convenience of description, a scale in which each of elements is illustrated in the accompanying drawings can differ from an actual scale. Thus, the illustrated elements are not limited to the specific scale in which they are illustrated in the drawings.

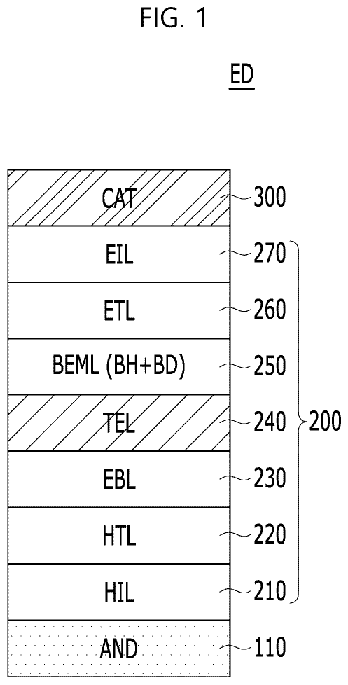

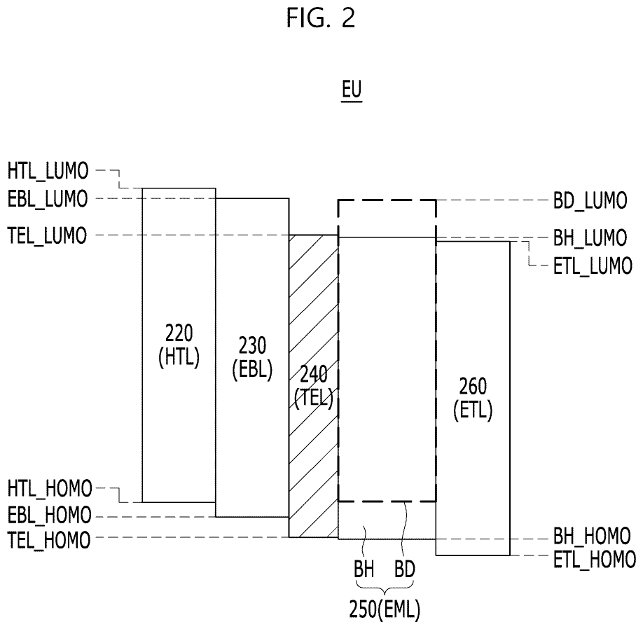

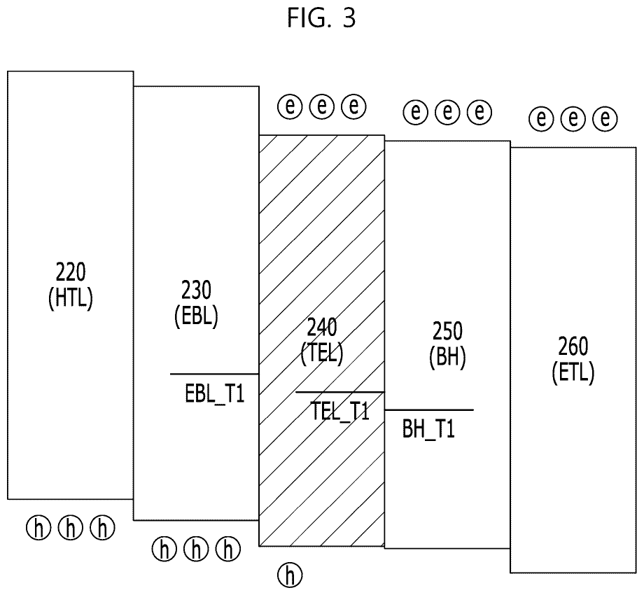

FIG. 1 is a sectional view illustrating a configuration of a light-emitting device according to some embodiments of the present disclosure. FIG. 2 shows an energy band diagram of each layer adjacent to an intermediate layer of the light-emitting device of the present disclosure, and FIG. 3 is a diagram showing charge distribution in the intermediate layer of the light-emitting device of the present disclosure.

As shown in FIG. 1, the light-emitting device according to some embodiments of the present disclosure has a first electrode 110 and a second electrode 300 facing each other, and a hole injection layer 210, a hole transport layer 220, an electron blocking layer 230, an energy transfer layer 240, a light-emitting layer 250, an electron transport layer 260, and an electron injection layer 270 provided in this order between the first electrode 110 and the second electrode 300.

One of the first electrode 110 and the second electrode 300 can be an anode and the other can be a cathode. One of the first electrode 110 and the second electrode 300 can be a reflective electrode, and the other thereof can be a transparent electrode or a semi-transparent electrode.

The first electrode 110 is connected to the thin film transistor provided on the substrate to selectively receive a signal supplied to each sub-pixel, and the second electrode 300 is provided in common among the sub-pixels and receives a common voltage.

The hole injection layer 210 can be formed of a hole injection material of a single organic or inorganic component, or can be formed of a hole transport material containing a p-type dopant. The hole injection layer 210 serves to reduce a barrier against supply of holes from the first electrode 110 to the intermediate layer 200.

For example, the hole transport layer 220 can be formed of an amine-containing hole transport material and transfers holes injected through the hole injection layer 210 to the light-emitting layer 250.

The electron injection layer 270 contacts the second electrode 300 and serves to reduce the barrier against injection of electrons from the second electrode 300 into the intermediate layer 200. The electron injection layer 270 can include a halogen atom bonded to an alkali metal or alkaline earth metal and/or an electron-transporting organic material.

For example, the electron transport layer 260 can be formed of an anthracene-containing electron transport material. The electron transport layer 260 transfers electrons from the electron injection layer 270 to the light-emitting layer 250.

In accordance with the light-emitting device of the present disclosure, holes transported through the hole injection layer 210 and the hole transport layer 220 are recombined with electrons transported through the electron injection layer 270 and the electron transport layer 260 when an electric field is generated by the voltage difference between the first electrode 110 and the second electrode 300 to form excitons, and the formed excitons fall to the ground state energy level, resulting in light emission.

In the light-emitting device of the present disclosure, the light-emitting layer 250 emits blue light, for example, and includes a boron-containing blue dopant BD and a host BH that transfers energy to the boron-containing blue dopant. Light emission in the light-emitting layer 250 is caused by energy level fluctuations in the blue dopant BD. Within the light-emitting layer 250, the blue dopant BD generates direct fluorescence by direct recombination of holes and electrons, and delayed fluorescence by exciton supply or energy transfer from the host BH and the energy transfer layer 240, which is an adjacent layer.

In a light-emitting device, luminous efficiency is optimal when holes recombine with electrons in the light-emitting layer. However, electrons transferred through the electron transport layer or some excitons in the light-emitting layer can pass over the light-emitting layer to the hole transport layer due to the difference in movement speed in the intermediate layer or the limited quantum efficiency of fluorescence.

The light-emitting device of the present disclosure includes an electron blocking layer 230 between the hole transport layer 220 and the light-emitting layer 250 to prevent electrons or excitons from passing to the hole transport layer. As shown in FIG. 2, the electron blocking layer 230 is formed of a material having a LUMO energy level (EBL_LUMO) higher than the LUMO energy level (BH_LUMO) of the blue host BH of the electron transport layer 260 and the light-emitting layer 250, thereby preventing electrons and excitons from passing from the light-emitting layer 250 to the hole transport layer 220 and preventing reduction in lifespan due to accumulation of excitons and electrons in the hole transport layer 220.

The electron blocking layer 230 is formed of a material that has a larger band gap than the energy transfer layer 240 and the host BH of the light-emitting layer 250. For example, the electron blocking layer 230 can be selected from a material having a high LUMO energy level (EBL_LUMO) among materials having hole transport properties.

In addition, the light-emitting device of the present disclosure further includes an energy transfer layer 240 between the electron blocking layer 230 and the light-emitting layer 250. The energy transfer layer 240 transfers energy to the light-emitting layer 250 due to the increased exciton density to activate triplet-triplet fusion (TTF) in the light-emitting layer 250, thereby contributing to the generation of delayed light emission.

As shown in FIG. 2, the LUMO energy levels (HTL_LUMO, EBL_LUMO, TEL_LUMO, BH_LUMO, ETL_LUMO) gradually decrease in the order of the hole transport layer 220, the electron blocking layer 230, the energy transfer layer 240, the host BH of the light-emitting layer 250, and the electron transport layer 260. Electrons move depending on the sequential LUMO energy levels of respective layers, and the difference between the LUMO energy level (EBL_LUMO) of the electron blocking layer 230 and the LUMO energy level of the energy transfer layer 240 is larger than that at the interfaces of other layers, thus acting as a barrier and preventing the flow of electrons from the energy transfer layer 240 through the electron blocking layer 230.

Meanwhile, the LUMO energy level (EBL_LUMO) of the electron blocking layer 230 is preferably set to be at least 0.1 eV greater than the LUMO energy level (TEL_LUMO) of the energy transfer layer 240 to prevent electrons and excitons from crossing the electron blocking layer 230. The difference between the LUMO energy levels of the energy transfer layer 240 and the host of the light-emitting layer (|TEL_LUMO-BH_LUMO|) and the difference between the LUMO energy levels of the host of the light-emitting layer and the electron transport layer (|BH_LUMO-ETL_LUMO|) are preferably smaller than 0.1 eV in terms of electron transfer.

In addition, the HOMO energy levels (HTL_HOMO, EBL_HOMO, TEL_HOMO, BH_HOMO, ETL_HOMO) gradually decrease in order of the hole transport layer 220, the electron blocking layer 230, the energy transfer layer 240, the host BH of light-emitting layer 250, and the electron transport layer 260.

The HOMO energy level (TEL_HOMO) of the energy transfer layer 240 can be approximately equal to the HOMO energy level (BH_HOMO) of the host of the light-emitting layer, and the LUMO energy level (TEL_LUMO) of the energy transfer layer 240 can be approximately equal to the LUMO energy of the host of the light-emitting layer (BH_LUMO). The material for the energy transfer layer 240 can have approximately the same energy band gap as the host BH of the light-emitting layer, but has different triplet energy level characteristics and thus serves to transfer the energy by excitons contained in the energy transfer layer 240 to the host of the light-emitting layer. For energy transfer, the triplet energy level of the energy transfer layer 240 is higher than the triplet energy level of the host BH of the light-emitting layer.

The HOMO energy level and LUMO energy level of each layer in the intermediate layer 200 described herein are values located below the vacuum energy level and thus have negative values. Therefore, the high HOMO energy level and high LUMO energy level of a layer mean that they are close to the vacuum energy level (0 eV) and absolute values thereof are small, and the low HOMO energy level and low LUMO energy level of a layer mean that they are far from the vacuum energy level (0 eV) and absolute values thereof are great.

Meanwhile, the blue dopant BD is present in an amount of 0.1 wt % to 10 wt % in the light-emitting layer 250 and contributes to direct light emission and delayed light emission. Therefore, the triplet energy level of the energy transfer layer 240 is higher than the triplet energy level of the host BH in the light-emitting layer 250, so that energy transfers to the triplet energy level of the host BH in the light-emitting layer 250 adjacent to the energy transfer layer 240 and triplets not used for light emission in the light-emitting layer combine with each other (TTF: triplet-triplet fusion) and are thus excited to the hot state energy level (Tn). In the host, the energy level from the hot state drops to the singlet energy level, energy is transferred to the singlet energy level of the blue dopant, the energy drops from the singlet energy level to the ground state, and delayed light emission can occur.

As the energy transfer from the energy transfer layer 240 to the host in the light-emitting layer increases, the TTF efficiency in the light-emitting layer increases, which means that the delayed light emission efficiency by triplet in the light-emitting layer 250 is improved. Since the energy transfer layer 240 contributes to improvement of TTF efficiency, the energy transfer layer 240 can be referred to as a “TTF enhancement layer”.

The blue dopant BD has a higher LUMO energy level (BD_LUMO) than the energy transfer layer 240 and plays a primary role in preventing the flow of excitons from within the light-emitting layer 250 to the outside.

As shown in FIG. 3, the energy transfer layer 240 is formed of a component whose electron transport properties are relatively superior to those of the electron blocking layer 230, so that excitons formed by recombination of electrons passing from the light-emitting layer 250 with holes passing through the electron blocking layer 230 can be generated at a high density at the interface of the electron blocking layer 230 and the energy transfer layer 240, and the excitons generated in the energy transfer layer 240 can be used to transfer energy to the host of the light-emitting layer 250.

The energy transfer layer 240 functions to transfer energy from excitons and electrons in the path from the light-emitting layer 250 to the electron blocking layer 230 to the host of the adjacent light-emitting layer 250 and thus increase the light emission TTF efficiency in the light-emitting layer.

The energy transfer layer 240 can be formed of, for example, [TEL-1] to [TEL-12] materials.

The hole transport layer 220 can be formed of, for example, the following materials [HTL-1] to [HTL-6].

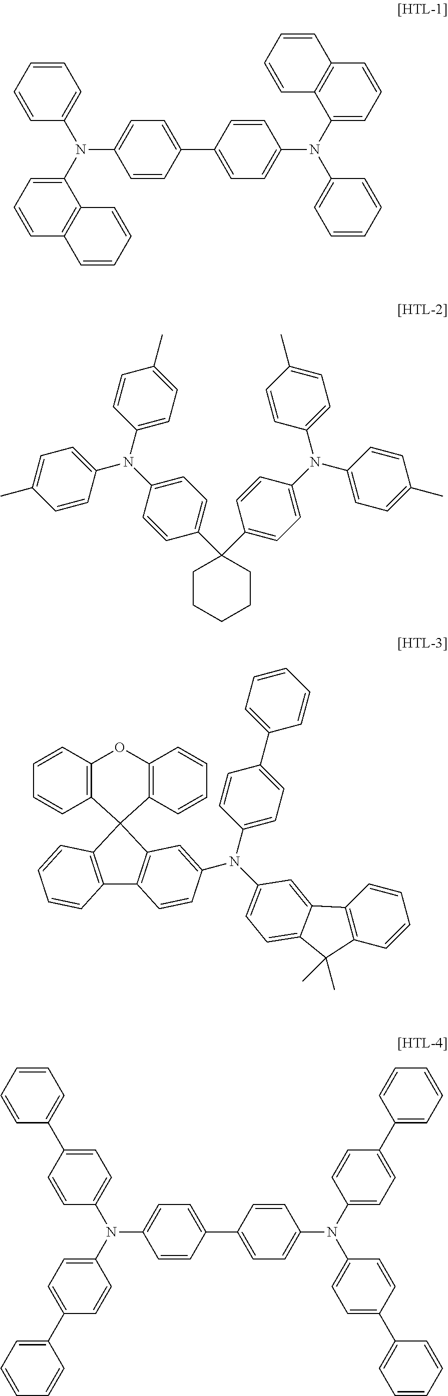

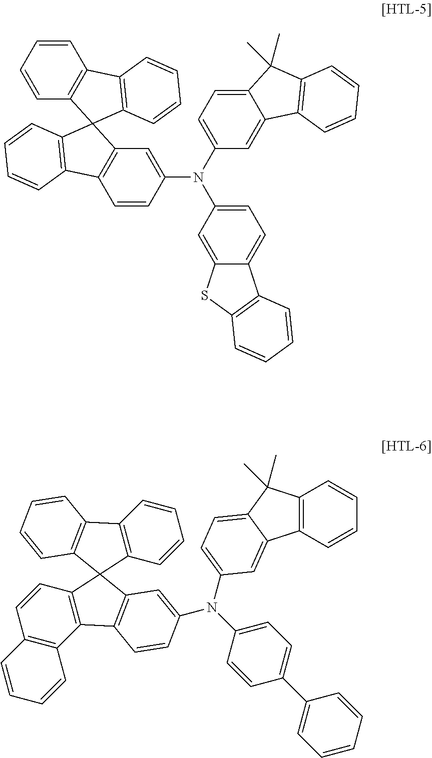 [SMILES: CC1(C)c2ccccc2-c2cc(N(c3ccc4c(c3)C3(c5ccccc5-c5ccccc53)c3ccccc3-4)c3ccc4c(c3)sc3ccccc34)ccc21 ; CC1(C)c2ccccc2-c2cc(N(c3ccc(-c4ccccc4)cc3)c3ccc4c(c3)C3(c5ccccc5-c5ccccc53)c3ccc5ccccc5c3-4)ccc21]

For example, the electron blocking layer 230 can be made of the following materials [EBL-1] to [EBL-7].

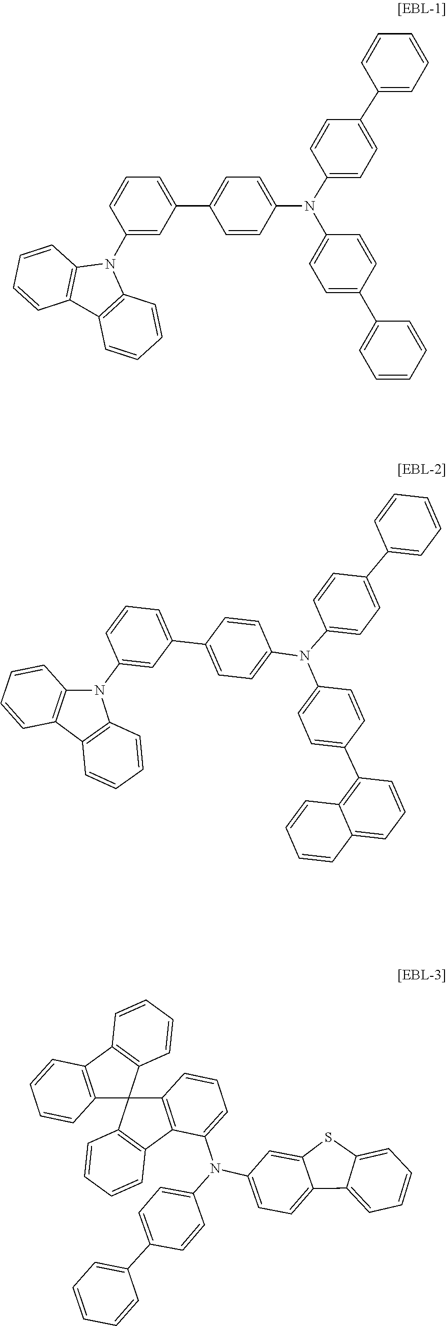 [SMILES: c1ccc(-c2ccc(N(c3ccc(-c4ccccc4)cc3)c3ccc(-c4cccc(-n5c6ccccc6c6ccccc65)c4)cc3)cc2)cc1 ; c1ccc(-c2ccc(N(c3ccc(-c4cccc(-n5c6ccccc6c6ccccc65)c4)cc3)c3ccc(-c4cccc5ccccc45)cc3)cc2)cc1 ; c1ccc(-c2ccc(N(c3ccc4c(c3)sc3ccccc34)c3cccc4c3-c3ccccc3C43c4ccccc4-c4ccccc43)cc2)cc1]

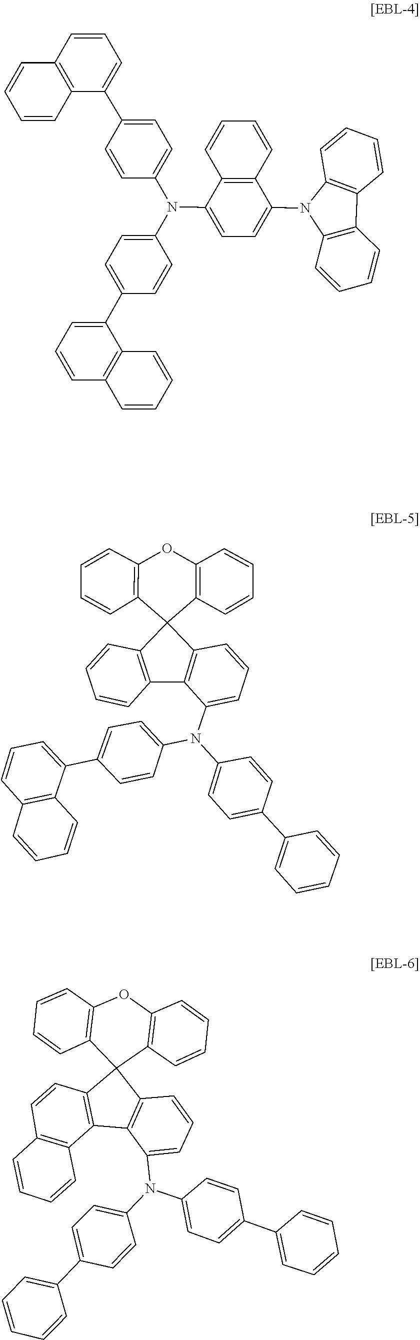 [SMILES: c1ccc2c(-c3ccc(N(c4ccc(-c5cccc6ccccc56)cc4)c4ccc(-n5c6ccccc6c6ccccc65)c5ccccc45)cc3)cccc2c1 ; c1ccc(-c2ccc(N(c3ccc(-c4cccc5ccccc45)cc3)c3cccc4c3-c3ccccc3C43c4ccccc4Oc4ccccc43)cc2)cc1 ; c1ccc(-c2ccc(N(c3ccc(-c4ccccc4)cc3)c3cccc4c3-c3c(ccc5ccccc35)C43c4ccccc4Oc4ccccc43)cc2)cc1]

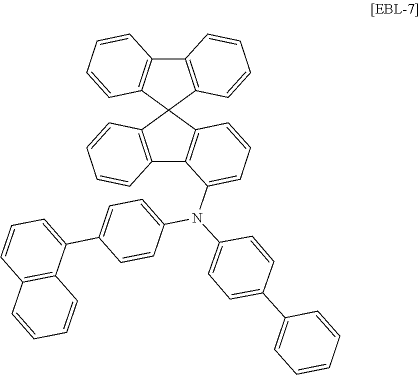 [SMILES: c1ccc(-c2ccc(N(c3ccc(-c4cccc5ccccc45)cc3)c3cccc4c3-c3ccccc3C43c4ccccc4-c4ccccc43)cc2)cc1]

In addition, the energy transfer layer 240 can contain pyrene, such as the materials [TEL-1] to [TEL-7], which have electron transport properties, in order to participate in energy transfer and electron transport.

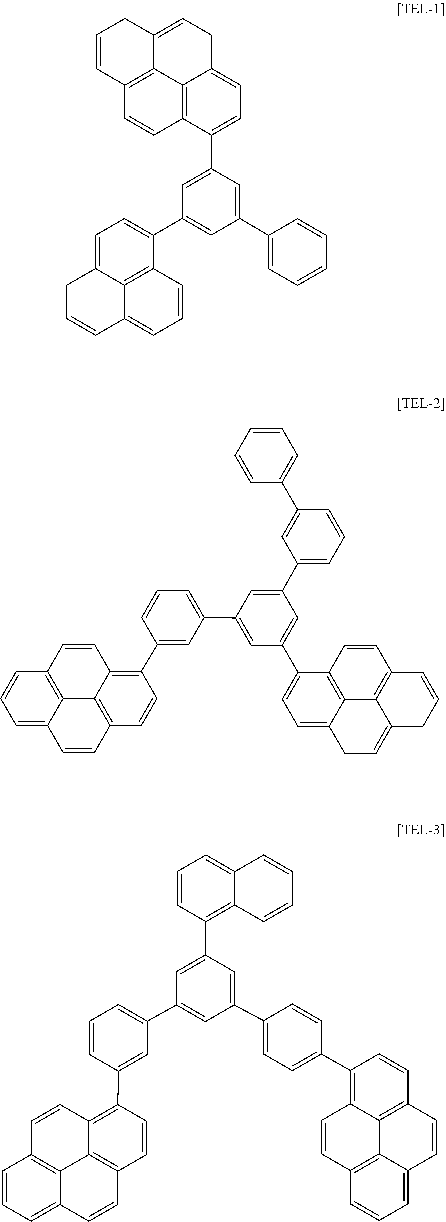

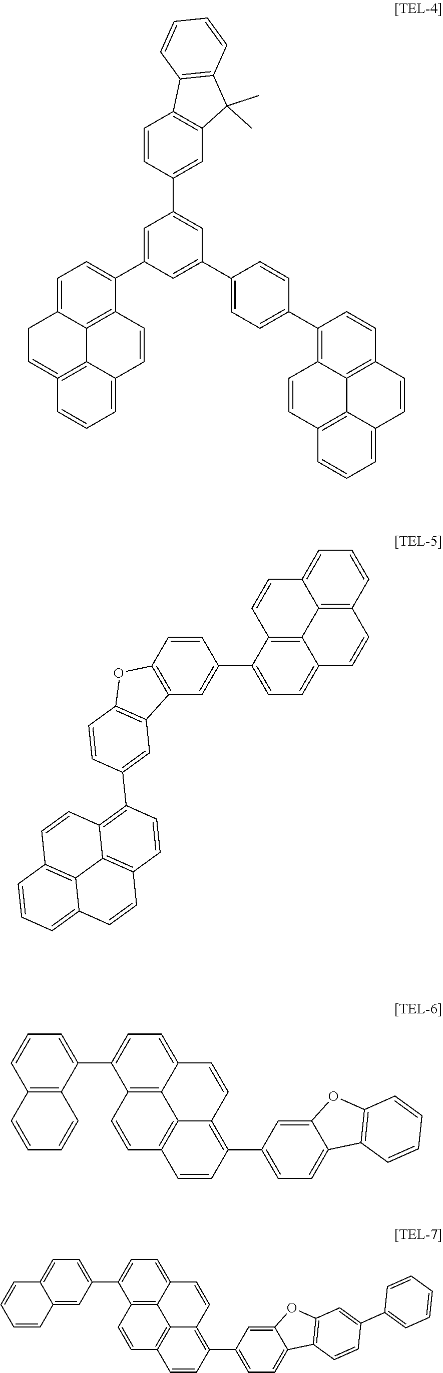

In order to inhibit the phenomenon in which electrons or excitons passing through the light-emitting layer 250 to the energy transfer layer 240 move to the electron blocking layer 230 and trap at the interface with the electron blocking layer 230, thus causing cause deterioration, the energy transfer layer 240 can have a structure in which at least one hydrogen of pyrene, phenylene, or naphthalene is substituted with deuterium (D), as shown in [TEL-8] to [TEL-12].

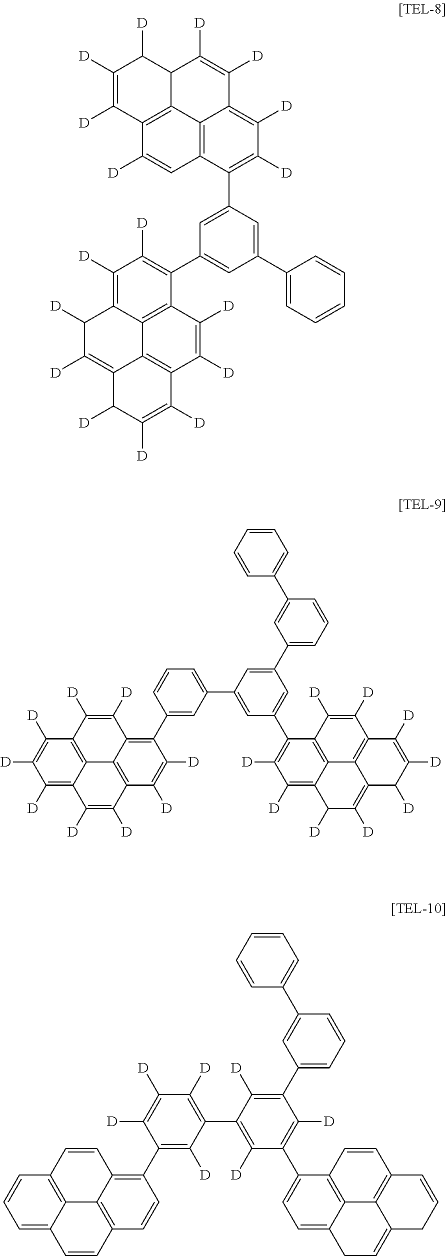

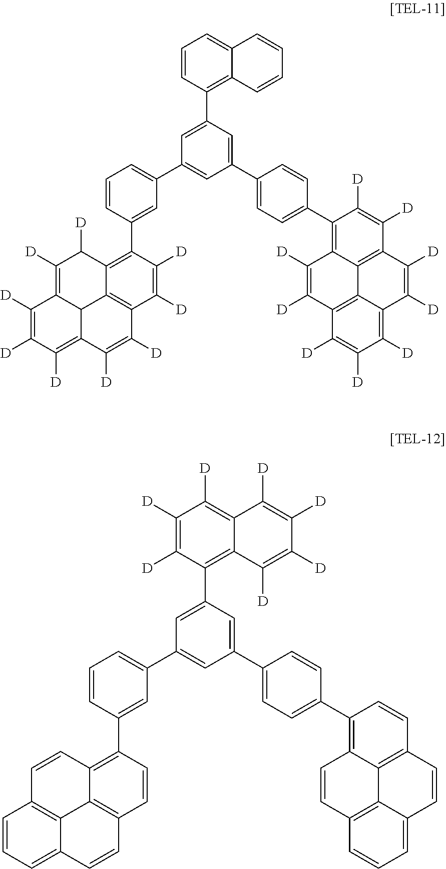 [SMILES: [2H]C1=C([2H])C2=C([2H])C([2H])c3c(-c4cccc(-c5cc(-c6ccc(-c7c([2H])c([2H])c8c([2H])c([2H])c9c([2H])c([2H])c([2H])c%10c([2H])c([2H])c7c8c9%10)cc6)cc(-c6cccc7ccccc67)c5)c4)c([2H])c([2H])c4c3C2C(=C1[2H])C([2H])=C4[2H] ; [2H]c1c([2H])c([2H])c2c(-c3cc(-c4ccc(-c5ccc6ccc7cccc8ccc5c6c78)cc4)cc(-c4cccc(-c5ccc6ccc7cccc8ccc5c6c78)c4)c3)c([2H])c([2H])c([2H])c2c1[2H]]

The host of the light-emitting layer 250 can be formed of materials [BH-1] to [BH-6].

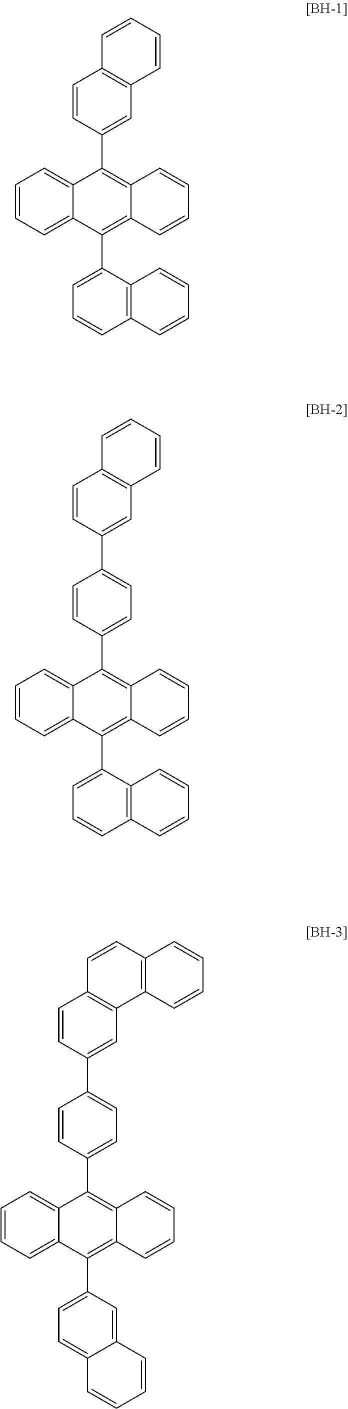

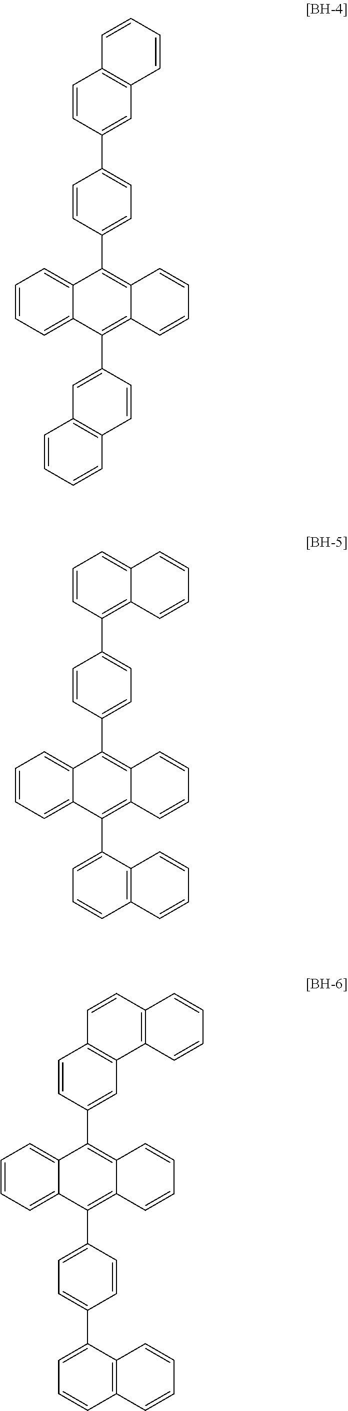

For example, the blue dopant of the light-emitting layer 250 can be formed of a material selected from [BD-1] to [BD-6].

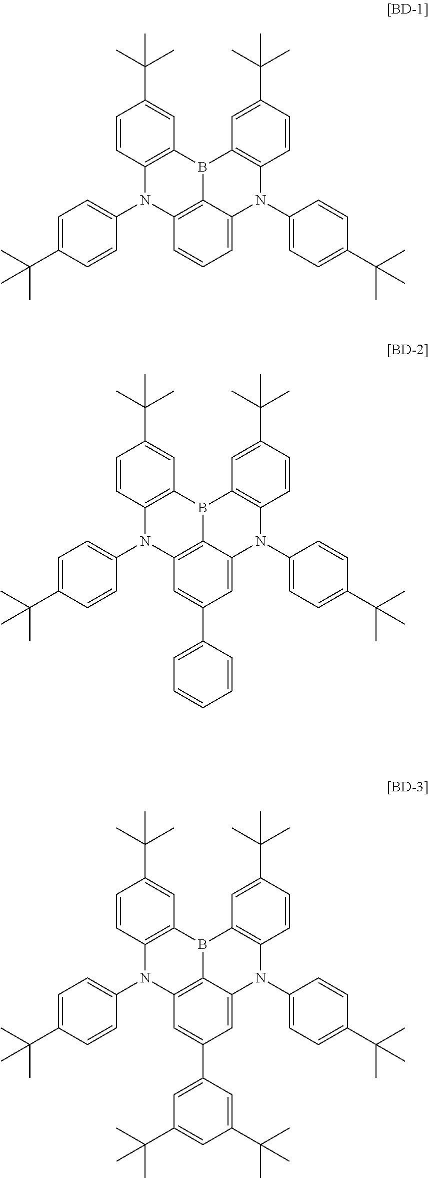

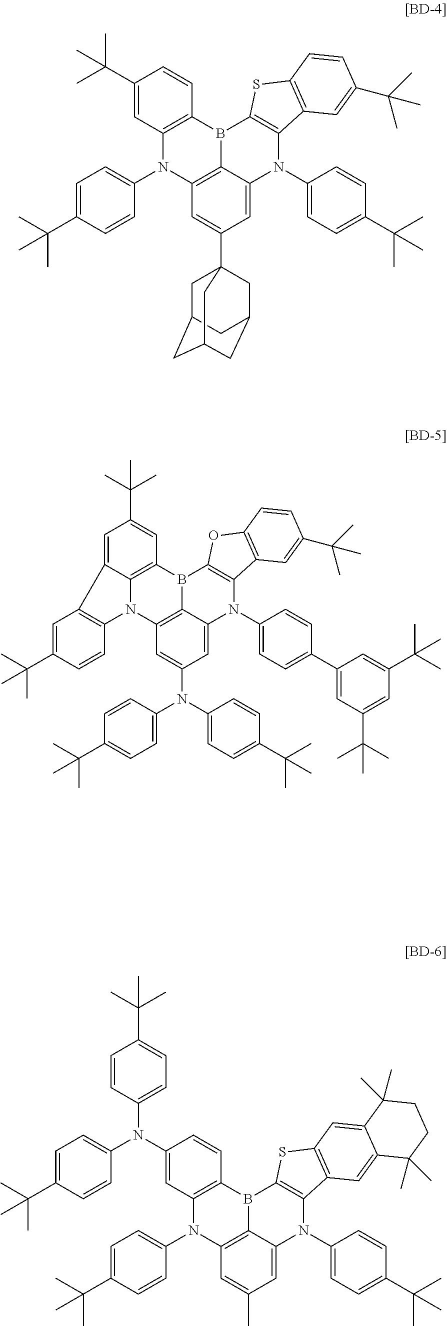

The materials for the hole transport layer, the electron blocking layer, the energy transfer layer, and the light-emitting layer described above are provided as examples and can be changed to other materials that satisfy the energy band diagram and charge distribution in FIGS. 2 and 3.

Hereinafter, the improvement effect of the light-emitting device of the present disclosure will be determined through experiments.

### Experiment 1

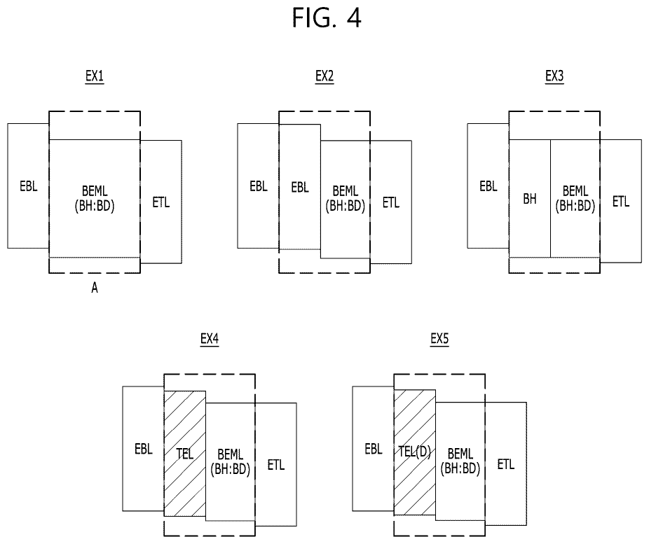

FIG. 4 shows the structure of Experimental Examples 1 to 5 used in Experiment 1.

Experimental Examples 1 to 5 (EX1 to EX5) shown in FIG. 4 have different configurations between the electron blocking layer and the electron transport layer. The remaining configuration between the first electrode and the second electrode of Experimental Examples 1 to 5 are shown in FIG. 1.

Experimental Example 1 (EX1) is an example in which an energy transfer layer is not provided between the light-emitting layer (BH:BD) and the electron blocking layer EBL, and has a structure in which the energy transfer layer is removed from the structure of FIG. 1.

The light-emitting device of Experimental Example 1 (Ex1) of Experiment 1 is manufactured as follows.

ITO is deposited to a thickness of 1,100 Å on a substrate to form a first electrode AND.

Any one material of [HTL-1] to [HTL-6] is doped with 10 wt % of a p-dopant to a thickness of 100 Å on the first electrode AND to form a hole injection layer HIL.

Next, any one of [HTL-1] to [HTL-6] is deposited to a thickness of 600 Å on the hole injection layer HIL to form a hole transport layer HTL.

Next, any one of [EBL-1] to [EBM-7] is deposited to a thickness of 150 Å on the hole transport layer HTL to form an electron blocking layer EBL.

Next, any one of [BH-1] to [BH-6] as a host on the electron blocking layer EBL is doped at 2 wt % with any one single blue dopant of [BD-1] to [BD-6] to a thickness of 300 Å to form a light-emitting layer BEML.

Next, an anthracene-containing material is deposited to a thickness of 230 Å on the light-emitting layer BEML to form an electron transport layer ETL.

Next, LiF is deposited to a thickness of 10 Å on the electron transport layer ETL to form an electron injection layer EIL.

Next, aluminum is deposited to a thickness of 700 Å on the electron injection layer EIL to form a second electrode CAT.

Experimental Examples 2 to 5 (EX2, EX3, EX4, EX5) have a configuration in which a 300 Å thick region occupied by the light-emitting layer (BH:BD) in Experimental Example (EX1) is divided into a 50 Å thick pre-part and a 250 Å light-emitting layer part. The 50 Å thick region contacting the electron blocking layer EBL is formed of a different material from the light-emitting layer (BH:BD). Experimental Example 2 (EX2) has a configuration in which a pre-part is formed between the blocking layer EBL and the light-emitting layer (BH:BD) using the same material as the material of the electron blocking layer EBL. Experimental Example 3 (EX3) has a configuration in which a pre-part is formed only with the host contained in the light-emitting layer (BH:BD). Experimental Example 3 (EX3) differs in the presence or absence of dopants in the pre-part and the light-emitting layer part. Experimental Example 4 (EX4) has a configuration in which a pre-part is formed using materials [TEL-1] to [TEL-7]. Experimental Example 5 (EX5) has a configuration in which a pre-part is formed using a deuterium-substituted material, such as [TEL-8] to [TEL-12]. The pre-parts between the electron blocking layer EBL and the light-emitting layer (BH:BD) of Experimental Examples 2 to 5 (EX2, EX3, EX4, and EX5) are each formed of only a single material without a dopant (ND).

In Experiment 1, IVL characteristics and T95 lifespan of Experimental Examples 1 to 5 (EX1, EX2, EX3, EX4, and EX5) were determined. IVL characteristics were determined by calculating the TTF ratio at a current density of 10 mA/cm². T95 lifespan refers to time elapsed until the luminance reaches 95% of the initial luminance, and is obtained by measuring the elapsed time until the luminance reaches 95% of the initial luminance at a driving temperature of 40° C. and a current density of 40 mA/cm².

TABLE 1

| | | | | T95 |
|---|---|---|---|---|
| | | | IVL@10 | @40° C., |
| | Material | | mA/cm² | 40 mA/cm² |
| | | Light-emitting | TTF ratio | Lifespan |
| Item | Pre-part | layer part BEML | (%) | (%) |
| EX1 | BH + BD (300 Å_2 wt %) | | 30.1 | 100% |
| EX2 | EBL | BH + BD | 30.5 | 107% |
| | (50 Å_ND) | (250 Å_2 wt %) | | |
| EX3 | BH | BH + BD | 29.0 | 24% |
| | (50 Å_ND) | (250 Å_2 wt %) | | |
| EX4 | TEL | BH + BD | 32.3 | 143% |
| | (50 Å_ND) | (250 Å_2 wt %) | | |
| EX5 | TEL (deuterium | BH + BD | 32.2 | 178% |
| | substitution) | (250 Å_2 wt %) | | |
| | (50 Å_ND) | | | |

As can be seen from the TTF ratios of Experimental Examples 1 to 5 in Table 1, compared to Experimental Example 1 (EX1), Experimental Example 2 (EX2) and Experimental Examples 4 and 5 (EX4, EX5) exhibit improved TTF efficiency and lifespan. However, Experimental Examples 4 and 5 (EX4, EX5) that further include a separate energy transfer layer TEL between the light-emitting layer region BEML and the electron blocking layer EBL exhibits greatly improved TTF ratio and lifespan than Experimental Example 2 (EX2) that includes an electron blocking layer EBL adjacent to the light-emitting layer part BEML.

Based on 100% of the TTF ratio of Experimental Example 1 (EX1), Experimental Example (EX2) is improved to 101% and Experimental Examples 4 and 5 (EX4, EX5) are improved to 107%. This means that delayed light emission is effective when the energy transfer layer TEL is provided. This effect is due to an increase in triplet density in the light-emitting layer due to Dexter energy transfer from the triplet energy level of the energy transfer layer TEL to the triplet energy level of the host of the light-emitting layer. In addition, comparing the lifespan between Experimental Example 4 (EX4) and Experimental Example 5 (EX5), Experimental Example (EX5) in which the material of the energy transfer layer is replaced with deuterium is highly effective in improving the lifespan.

Meanwhile, in Experimental Example 1, the triplet energy levels of the hosts of the electron blocking layer, the energy transfer layer, and the light-emitting layer of Experimental Examples 1 to 5 are shown in Table 2.

TABLE 2

| Item | Triplet energy level (eV) |
|---|---|
| EBL_T1 | 2.5 eV |
| TEL_T1 | 2.1 eV |
| BH_T1 | 1.7 eV |

Hereinafter, the delayed fluorescence emission mechanism of Experimental Examples 1 to 5 will be described.

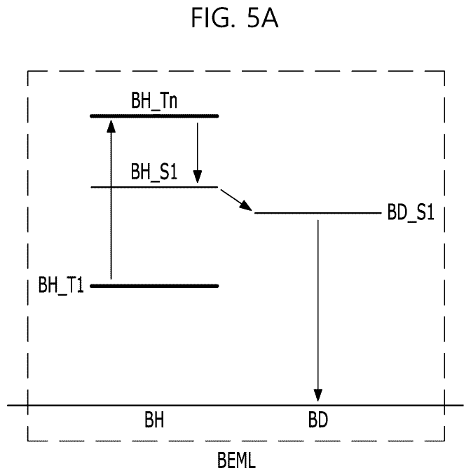

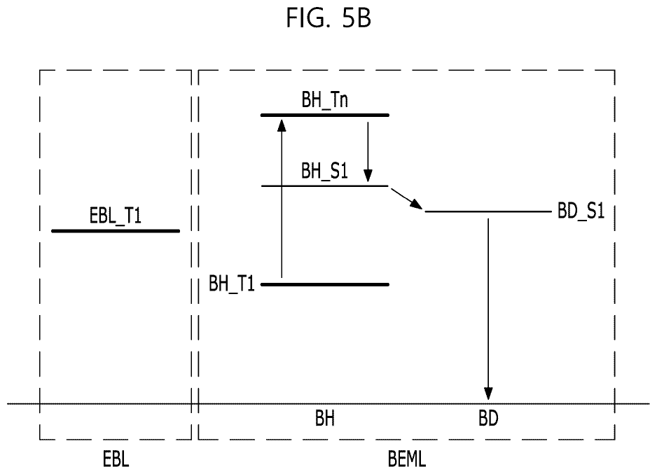

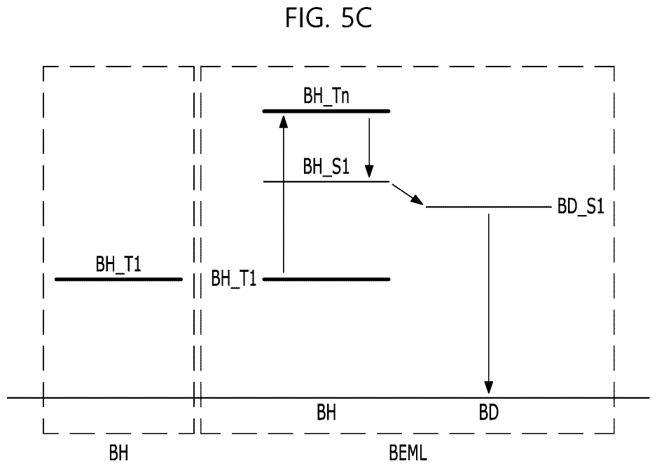

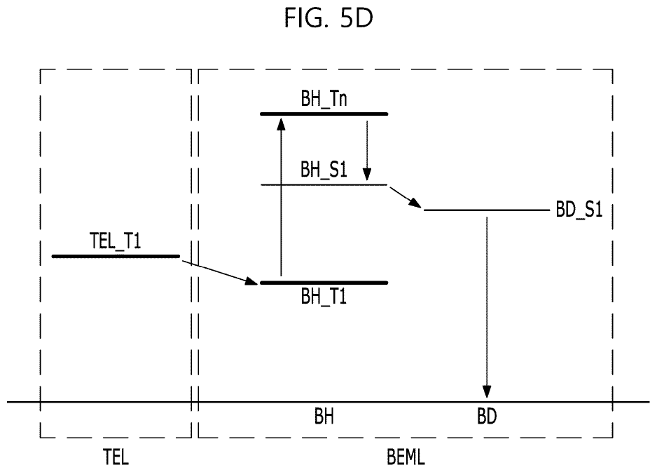

FIG. 5A shows the delayed fluorescence emission mechanism of Experimental Example 1. FIG. 5B shows the delayed fluorescence emission mechanism of Experimental Example 2. FIG. 5C shows the delayed fluorescence emission mechanism of Experimental Example 3. FIG. 5D shows the delayed fluorescence emission mechanism of Experimental Examples 4 and 5.

In Experimental Example 1 (EX1) shown in FIG. 5A, the light-emitting layer can generate delayed fluorescence in the dopant due to energy transfer based on the difference between the TTF in the host and the singlet energy level of the host and the singlet energy level of the dopant.

In Experimental Example 2 (EX2) shown in FIG. 5B, the electron blocking layer EBL is located in a pre-part of the light-emitting layer. Like FIG. 5A, the electron blocking layer material has a very large triplet energy level which is greatly different from the triplet energy level, thus causing no energy transfer from the electron blocking layer to the light-emitting layer. However, in Experimental Example 2 (EX2), TTF efficiency and lifespan are slightly improved by restricting the exciton generation area through reduced emission area.

In Experimental Example 3 (EX3) shown in FIG. 5C, the host material of the light-emitting layer is disposed in the pre-part of the light-emitting layer (BH:BD), thus causing no energy transfer due to the same triplet energy level between the pre-part and the host of the light-emitting layer. Electrons flow into the pre-part, out of the light-emitting layer, thus resulting in a decrease in TTF efficiency and a significant decrease in lifespan.

As shown in FIG. 5D, unlike Experimental Example 3 (EX3), in Experimental Example 4 (EX4) and Experimental Example 5 (EX5), the triplet energy level of the energy transfer layer 240 is higher than the triplet energy level of the host BH in the light-emitting layer (TEL_T1>BH_T1). Referring to Table 2, the triplet energy level of the energy transfer layer 240 is lower than the triplet energy level of the electron blocking layer (TEL_T1<EBL_T1). For example, the triplet energy level of the energy transfer layer 240 in Experimental Example 4 (EX4) and Experimental Example 5 (EX5) is appropriately different from the energy level of the light-emitting layer to transfer energy to the triplet energy level of the host of the light-emitting layer. The triplet level (TEL_T1) of the energy transfer layer 240 can be about 0.1 eV to about 0.79 eV greater than the triplet level (BH_T1) of the host of the light-emitting layer.

In addition, the triplet energy level (TEL_T1) of the energy transfer layer 240 is greater than the triplet energy level (BH_T1) of the host (TEL_T1>BH_T1) and is smaller than the singlet energy level of the host (TEL_T1<BH_S1) in terms of energy transfer.

The singlet energy level (BH_S1) of the host is less than twice the triplet energy level (BH_T1) of the host (BH_S1<2BH_T1), and twice the triplet energy level of the host (2BH_T1) can be smaller than the excitation energy level (Tn) (Tn>2BH_T1) of the TTF (triplet-triplet fusion) of the host (Tn>2BH_T1).

Therefore, the hosts of the adjacent energy transfer layer and the light-emitting layer have the following relationship.

BH_Tn>BH_2T1>BH_S1>TEL_T1>BH_T1

Meanwhile, in Experiment 2 below, the difference in characteristics when the energy transfer layer is different from that of Experimental Example 1 will be determined.

### Experiment 2

TABLE 3

| | | | | T95 | TEL |
|---|---|---|---|---|---|
| | | | | @40° C., | thickness |
| | | | IVL@10 | 40 mA/ | compared to |
| | | | mA/cm² | cm² | the dotted |
| | Material | | TTF ratio | Lifespan | line area |
| Item | TEL | B EML | (%) | (%) | in FIG. 4 |
| EX1 | BH + BD (300 Å_2 wt %) | | 30.1 | 100% | — |
| EX6 | TEL | BH + BD | 32.2 | 133% | 10% |
| | (30 Å) | (270 Å_2 wt %) | | | |
| EX4 | TEL | BH + BD | 32.3 | 143% | 16.7% |
| | (50 Å) | (250 Å_2 wt %) | | | |
| EX7 | TEL | BH + BD | 29.9 | 121% | 33.3% |
| | (100 Å) | (200 Å_2 wt %) | | | |
| EX8 | TEL | BH + BD | 27.7 | 106% | 50% |
| | (150 Å) | (150 Å_2 wt %) | | | |

Experiment 2 was conducted to determine the IVL characteristics and T95 lifespan when setting the thicknesses of the ratio (percentage) of the total thickness of the energy transfer layer and the light-emitting layer BEML to the energy transfer layer TEL in Experimental Example 6 (EX6), Experimental Example 4 (EX4), Experimental Example 7 (EX7), and Experimental Example 8 (EX8) were 10%, 16.7%, 33.3%, and 50%.

As a result of measurement of the TTF efficiency, both Experimental Example 6 (EX6) and Experimental Example 4 (EX4) show improved results, but like Experimental Example 8 (EX8), TTF efficiency actually decreases when the thickness of the energy transfer layer TEL is higher than 150 Å. In Experimental Example 7 (EX7), when the thickness of the energy transfer layer TEL is 100 Å, the TTF efficiency is similar to Experimental Example 1 (EX1), and the lifespan is improved to 121% compared to Experimental Example 1 (EX1).

In all cases, Experimental Example 6 (EX6), Experimental Example 4 (EX4), Experimental Example 7 (EX7), and Experimental Example 8 (EX8) showed improved results in terms of lifespan. TTF efficiency and lifespan exhibit the highest efficiency when the thickness of the energy transfer layer is 16.7% compared to the total thickness of the energy transfer layer and the light-emitting layer BEML, and thereafter, as the thickness of the energy transfer layer increases, the lifespan decreases. Since the TTF efficiency remarkably decreases when the thickness of the energy transfer layer is higher than 50% of the total thickness of the energy transfer layer and the light-emitting layer BEML, the thickness of the energy transfer layer is preferably not greater than the thickness of the light-emitting layer. In addition, the energy transfer layer must be formed at a predetermined thickness or more to secure reproducibility and ensure process uniformity. Therefore, it is preferable to form the energy transfer layer to a thickness of 10% or more of the total thickness of the energy transfer layer and the light-emitting layer BEML.

Hereinafter, the properties of the energy transfer layer of the light-emitting device of the present disclosure will be evaluated through the following experiment.

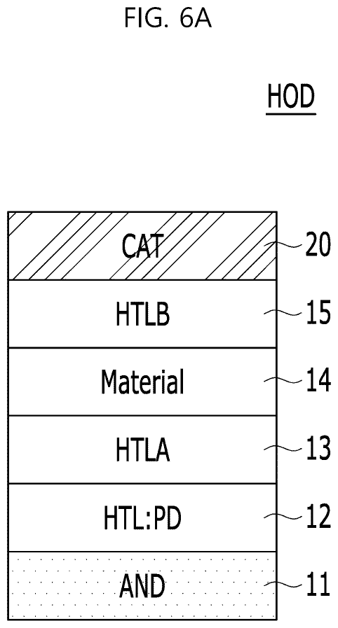

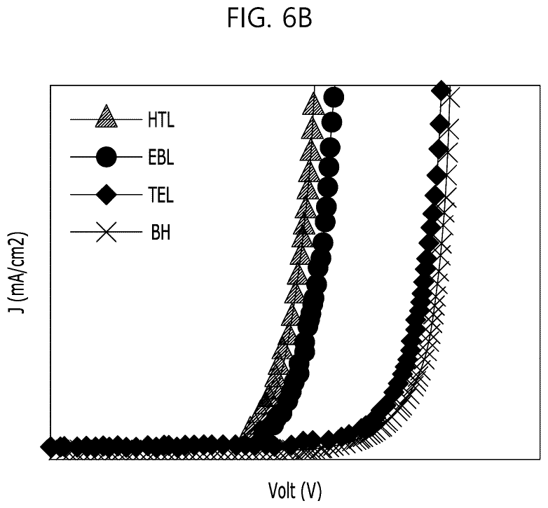

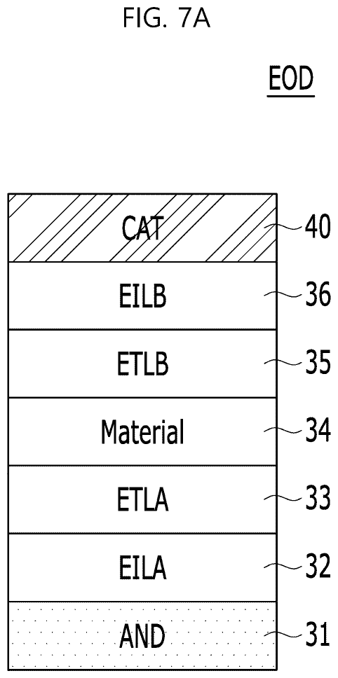

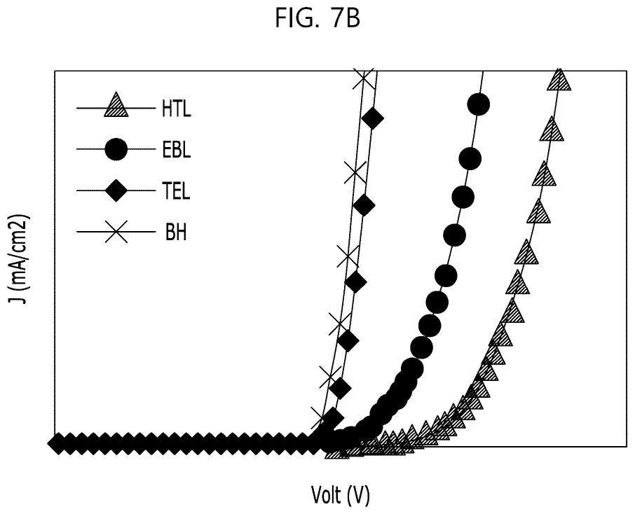

FIG. 6A is a cross-sectional view illustrating the HOD used in Experiment 3, and FIG. 6B is a graph showing IV characteristics for each material used in the HOD of FIG. 6A. FIG. 7A is a cross-sectional view illustrating the HOD used in Experiment 4 and FIG. 7B is a graph showing IV characteristics for each material used in the EOD of FIG. 7A.

### Experiment 3

As shown in FIG. 6A, the HOD (hole only device) used in Experiment 3 is a device to determine the hole transport characteristics of the material layer, and contains a main material, which is a hole transport material as a transport material between the first electrode 11 and the second electrode 20 to observe the flow of holes and a material layer is provided to determine JV characteristics of the hole transport material.

As shown in FIG. 6A, the HOD used in Experiment 3 is formed through the following process.

As shown in FIG. 6A, the HOD used in Experiment 3 is formed through the following process.

ITO is deposited on the substrate to form a first electrode 11.

Next, a hole transport material HTL is doped with 10 wt % of a p-type dopant (PD) to a thickness of 100 Å on the first electrode 11, to form a hole injection layer 12.

Next, a hole transport material (HTLA) is deposited to a thickness of 200 Å on the hole injection layer 12 to form a first hole transport layer 13.

A material layer 14 is formed to a thickness of 500 Å on the first hole transport layer 13. In Experiment 3, the material layer is the subject for measuring current density compared to driving voltage, as shown in FIG. 6A. In Experimental Example 3, as shown in Table 4, the material layer 14 is formed using four different materials (a hole transport material HTL, an electron blocking material EBL, an energy transfer material TEL, and a host BH).

Next, a hole transport material (HTLB) is deposited to a thickness of 200 Å to form a second hole transport layer 15.

Next, a second electrode 20 is formed on the second hole transport layer 15.

In HOD, the hole injection layer 12, the first hole transport layer 13, and the second hole transport layer 15 can contain the same hole transport material.

As shown in FIG. 6B, the high driving voltage required to achieve the constant current density increases in this order of the hole transport material HTL, the electron blocking material EBL, the energy transfer material TEL, and the host BH.

In addition, the hole transport material HTL and the electron blocking material EBL exhibit similar JV curves, because the materials two have superior hole transport properties. On the other hand, required driving voltage are shifted in the energy transfer material TEL and the host BH compared to the hole transport material HTL, which indicates that the hole transport characteristics are poor.

### Experiment 4

Hereinafter, the hole transport characteristics of the material layer were evaluated through Experiment 3 using the EOD (electron only device) used in Experiment 3.

The EOD (electron only device) is a device to determine the hole transport characteristics of the material layer, and contains a main material, which is a hole transport material as a transport material between the first electrode 31 and the second electrode 40 to observe the flow of holes and a material layer is provided to determine JV characteristics of the hole transport material.

As shown in FIG. 7A, the EOD used in Experiment 4 is formed in the following process. ITO is deposited on a substrate to form a first electrode 31.

Next, LiF is deposited to a thickness of 10 Å on the first electrode 31 to form a first electron injection layer 32.

Next, an electron transport material is deposited to a thickness of 200 Å on the first electron injection layer 32 to form a first electron transport layer 33.

Next, a material layer 34 is formed to a thickness of 500 Å on the first electron transport layer 33. In Experiment 4, the material layer is the subject of measuring current density compared to driving voltage, as shown in FIG. 7A. In Experiment 4, as shown in Table 4, the material layer 34 was formed using four different materials (hole transport material HTL, electron blocking material EBL, the energy transfer material TEL, and the host BH)

Next, an electron transport material is deposited to a thickness of 200 Å to form a second electron transport layer 35.

Next, a second electrode 20 is formed on the second electron injection layer 36.

In EOD, the first and second electron transport layers 33 and 35 can be formed of the same electron transport material.

As shown in FIG. 7B, the driving voltage required to achieve the same current density decreases in this order of the hole transport material HTL, the electron blocking material EBL, the energy transfer material TEL, and the host BH.

In addition, it can be seen that the energy transfer material TEL and the host BH exhibit similar or same excellent electron transport characteristics.

The hole transport material HTL and the electron blocking material EBL have weak electron transport properties, but the electron blocking material EBL exhibits greater electron transport property than the hole transport material HTL.

The triplet energy and transport tendency of each material used in Experiments 3 and 4 are as shown in Table 4.

TABLE 4

| Material item | HTL | EBL | TEL | BH |
|---|---|---|---|---|
| T1(eV) | 2.5 | 2.5 | 2.1 | 1.7 |
| Transport | hole | hole | Electron | Electron |
| property | transport | transport | transport | transport |

Hereinafter, the device having a configuration in which the light-emitting device includes a plurality of stacks and the energy transfer layer contacts the blue light-emitting layer will be described.

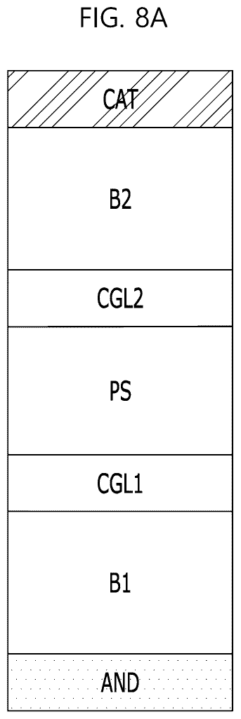

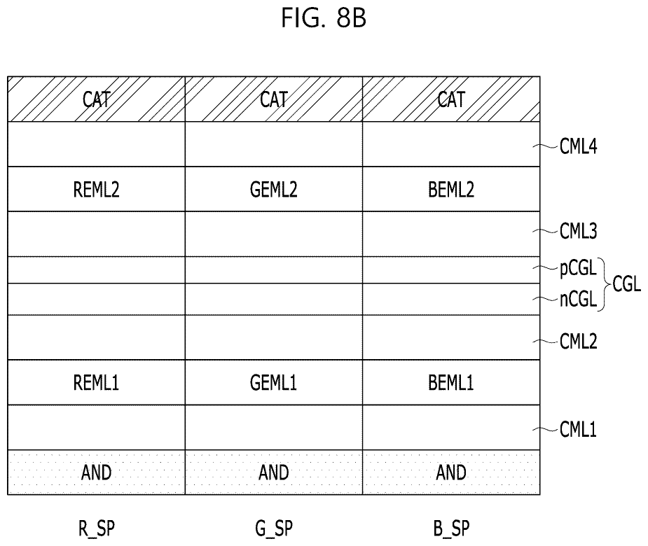

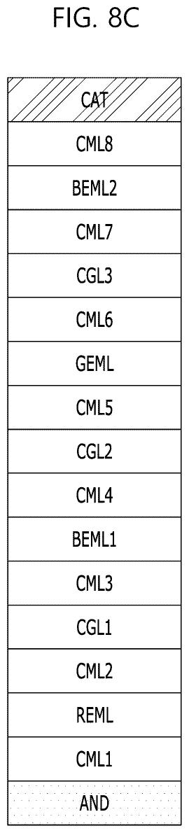

FIGS. 8A to 8C are cross-sectional views illustrating a light-emitting device according to some embodiments of the present disclosure.

As shown in FIG. 8A, the light-emitting device according to some embodiments of the present disclosure can include a plurality of stacks B1, PS, and B2 between a first electrode AND and a second electrode CAT.

Charge generation layers CGL1 and CGL2 are provided between the stacks B1, PS, and B2 to separate the stacks from each other.

The charge generation layers CGL1 and CGL2 can be formed as an n-type charge generation layer and a p-type charge generation layer.

Each of the plurality of stacks B1, PS, and B2 includes a hole transport layer, a light-emitting layer, and an electron transport layer, and holes or electrons are supplied from the electrodes AND and CAT or charge generation layers CGL1 and CGL2 adjacent to each stack, excitons can be generated in each stack and thus the multilayer stack can improve efficiency compared to a single stack.

The first blue stack B1 and the second blue stack B2 have a blue light-emitting layer that emits blue light, and, for example, contain at least one host of [BH-1] to [BH-6] described above and at least one blue dopant of [BD-1] to [BD-6]. In addition, the first and second blue stacks B1 and B2 that emit blue light further include an electron blocking layer between the hole transport layer and the light-emitting layer to control the flow of electrons and excitons from the blue light-emitting layer to the hole transport layer. For example, the first and second blue stacks B1 and B2 each include a hole transport layer, an electron blocking layer, a blue light-emitting layer, and an electron blocking layer.

A phosphorescent stack PS including a phosphorescent light-emitting layer is provided between the first and second blue stacks B1 and B2. In order for the light-emitting device according to FIG. 8A to emit white light, the phosphorescent stack PS can further include a phosphorescent light-emitting layer with a longer wavelength than bluc.

For example, the phosphorescent light-emitting layer of the phosphorescent stack PS can include a single yellow-green light-emitting layer or a single green light-emitting layer. According to some embodiments, the phosphorescent light-emitting layer of the phosphorescent stack PS can sequentially include a red light-emitting layer and a green light-emitting layer. According to some embodiments, the phosphorescent light-emitting layer of the phosphorescent stack PS can sequentially include a red light-emitting layer, a yellow-green light-emitting layer, and a green light-emitting layer. In some cases, at least one of the red light-emitting layer, the yellow-green light-emitting layer, and the green light-emitting layer can render the same color, but a plurality of light-emitting layers can be formed at different ratios between the plurality of hosts provided or different contents of the dopant.

For example, the phosphorescent stack PS can be formed in the following order: a hole transport layer, a red light-emitting layer, a yellow green light-emitting layer, a first green light-emitting layer, a second green light-emitting layer, and an electron transport layer. In some cases, when the phosphorescent stack PS includes a plurality of phosphorescent light-emitting layers, the phosphorescent light-emitting layer adjacent to the lower charge generation layer among the plurality of phosphorescent light-emitting layers can contribute to hole transport, and the phosphorescent light-emitting layer adjacent to the charge generation layer disposed thereon can contribute to electron transport. In some cases, the hole transport layer or electron transport layer can be omitted from the phosphorescent stack PS.

Meanwhile, although FIG. 8A shows an example where the phosphorescent stack PS is located between the first and second blue stacks B1 and B2, the light-emitting device of the present disclosure is not limited thereto. The phosphorescent stack PS can be formed adjacent to either the first electrode AND or the second electrode CAT. In some cases, from the viewpoint of improving color purity, the phosphorescent stack PS can be divided between the first electrode AND and the second electrode CAT depending on the color.

Meanwhile, the light-emitting device of the present disclosure further includes a hole injection layer in the first blue stack B1 adjacent to the first electrode AND among the plurality of stacks B1, PS, and B2 provided in FIG. 8A, and the second blue stack B2 adjacent to the second electrode CAT can further include an electron injection layer.

The light-emitting device of the present disclosure further includes an energy transfer layer (240 in FIG. 1) between the hole transport layer and the light-emitting layer or between the electron blocking layer and the light-emitting layer in any one of the stacks B1, PS, and B2 in FIG. 8A.

In addition, although the example shows three stacks, the embodiment of the light-emitting device of the present disclosure can have a configuration in which a single blue stack and a single phosphorescent stack are present between the first electrode and the second electrode with a charge generation layer interposed therebetween.

As shown in FIG. 8B, the light-emitting device according to some embodiments of the present disclosure includes a first electrode AND and a second electrode CAT facing each other, in each of a red sub-pixel R_SP, a green sub-pixel G_SP, and a blue sub-pixel B_SP, and a light-emitting layer having a plurality of stacks between the first electrode AND and the second electrode CAT and emitting the same color overlapping with each other in the plurality of stacks. For example, the red sub-pixel R_SP has red light-emitting layers REML1 and REML2 in separate stacks with a charge light-emitting layer CGL interposed therebetween, and the green sub-pixel G_SP includes green light-emitting layers GEML1 and GEML2 in separate stacks with a charge light-emitting layer CGL interposed therebetween, and the blue sub-pixel B_SP includes blue light-emitting layers BEML1 and BEML2 in separate stacks with a charge light-emitting layer CGL interposed therebetween.

Here, a first common layer CML1 related to hole injection and hole transport is provided between the first electrode AND, the first red light-emitting layer REML1, the first green light-emitting layer GEML1, and the first blue light-emitting layer BEML1, and a second common layer CML2 related to electron transport is provided between the first red light-emitting layer REML1, the first green light-emitting layer GEML1, the first blue light-emitting layer BEML1, and the charge generation layer CGL.

The charge generation layer CGL can be provided by stacking an n-type charge generation layer nCGL and a p-type charge generation layer pCGL.

In addition, a third common layer CML3 related to hole injection and hole transport is provided between the charge generation layer CGL, the second red light-emitting layer REML2, the second green light-emitting layer GEML2, and the second blue light-emitting layer BEML2, and a fourth common layer CML2 including an electron transport layer and an electron injection layer is provided between the second red light-emitting layer REML2, the second green light-emitting layer GEML2, the second blue light-emitting layer BEML2, and the second electrode CAT.

The first common layer CML1 and the third common layer CML3 include at least one of a hole injection layer, a hole transport layer, or an electron blocking layer, and the second common layer CML2 and the fourth common layer CML4 can include at least one of a hole blocking layer, an electron transport layer, or an electron injection layer.

The first common layer CML1 and the third common layer CML3 further include the energy transfer layer TEL contacting the first blue light-emitting layer BEML1 along with a hole transport layer and an electron blocking layer in the blue sub-pixel B_SP. In addition, the efficiency of generating TTF (triplet-triplet fusion) in the light-emitting layer is increased by the Dexter energy transfer process of excitons that are not used for direct light emission from the energy transfer layer to the host in the light-emitting layer, and the exciton energy is transferred to the singlet energy level of the light-emitting layer due to improved TTF efficiency, thereby improving luminous efficiency.

The energy transfer layer TEL can be selectively provided in the blue sub-pixel B_SP, or can extend partially or entirely to the red sub-pixel R_SP and the green sub-pixel G_SP, to improve TTF efficiency of the first red emitting layer REML1 or/and the first green emitting layer GEML1 located thercon. In the light-emitting device according to some embodiments of the present disclosure, the energy transfer layer provided in the red sub-pixel R_SP, the green sub-pixel G_SP, and the blue sub-pixel B_SP has a different relationship with the triplet energy level of the dopant and host of the adjacent light-emitting layer and thus has different substances therefrom.

In some embodiments of the present disclosure, a configuration in which two or more blue stacks and two or more phosphorescent stacks are present between the first electrode and the second electrode is also possible.

For example, as shown in FIG. 8C, the light-emitting device according to some embodiments of the present disclosure has four stacks divided by at least charge generation layers (CGL1, CGL2, and CGL3) between the first electrode AND and the second electrode CAT.

Each stack includes a light-emitting layer REML, BEML1, GEML, or BEML2 in the center thereof, a common layer related to hole transport CML1, CML3, CML5, or CML7 below the light-emitting layer REML, BEML1, GEML or BEML2, and a common layer CML1, CML3, CML5 or CML7 related to electron transport on the light-emitting layer REML, BEML1, GEML or BEML2.

As described above, the first common layer CML3 and the third common layer CML7 contacting the first blue light-emitting layer BEML1 or the second blue light-emitting layer BEML2 emitting blue light further include the energy transfer layer TEL contacting the first blue light-emitting layer BEML1 along with a hole transport layer and an electron blocking layer, thereby improving the efficiency of generating TTF (triplet-triplet fusion) in the light-emitting layer by the Dexter energy transfer process of excitons that are not used for direct light emission from the energy transfer layer to the host in the light-emitting layer, and the exciton energy is transferred to the singlet energy level of the light-emitting layer due to improved TTF efficiency, thereby improving luminous efficiency.

The arrangement of the four stacks shown in FIG. 8C is an example, and the first blue light-emitting layer BEML1 can be disposed in another stack.

Additionally, an additional stack in addition to the three or four stacks described above can be provided to improve the efficiency of the light-emitting device.

In a structure including a plurality of stacks, an energy transfer layer is further provided between at least the electron blocking layer and the blue light-emitting layer to improve the TTF efficiency of the blue light-emitting layer.

Hereinafter, the effect of a structure including an energy transfer layer in a light-emitting device including a blue stack with different stack configurations will be described.

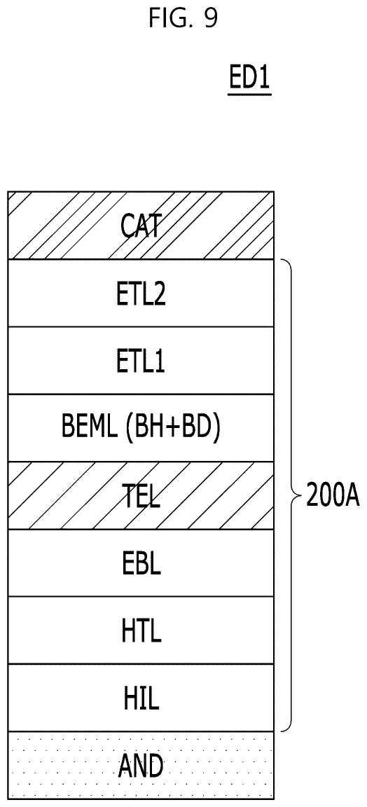

FIG. 9 is a cross-sectional view illustrating the light-emitting device used in Experiment 5.

As shown in FIG. 9, the light-emitting device used in Experiment 5 includes a stack configuration included in the first blue stack B1 of FIG. 8 between the first electrode AND and the second electrode CAT.

The light-emitting device of Experimental Example 9 (EX9) of Experiment 5 is manufactured as follows.

ITO is deposited to a thickness of 1,100 Å on a substrate to form a first electrode AND.

Any one of [HTL-1] to [HTL-6] materials and MgF₂ are co-deposited in a 1:1 ratio to a thickness of 70 Å on the first electrode AND, to form a hole injection layer HIL.

Next, any one of [HTL-1] to [HTL-6] is deposited to a thickness of 800 Å on the hole injection layer HIL to form a hole transport layer HTL.

Next, any one of [EBL-1] to [EBM-7] is deposited to a thickness of 150 Å on the hole transport layer HTL to form an electron blocking layer EBL.

Next, any one of [BH-1] to [BH-6] as a host on the electron blocking layer EBL is doped at 2 wt % with any one of [BD-1] to [BD-6] as a blue dopant to a thickness of 250 Å, to form a blue light-emitting layer BEML.

Next, an anthracene-containing material is deposited to a thickness of 170 Å on the light-emitting layer BEML to form a first electron transport layer ETL1.

Next, an anthracene-containing material is doped with 2 wt % Li on the first electron transport layer ETL1 to form a second electron transport layer ETL2.

Next, aluminum is deposited to a thickness of 700 Å on the second electron transport layer ETL2 to form a second electrode CAT.

The light-emitting device of Experimental Example 10 (EX10) differs from Experimental Example 9 (EX9) in that the electron blocking layer EBL and the blue light-emitting layer BEML are further formed as an energy transfer layer TEL.

In Experiment 5, the energy transfer layer TEL is formed using any one of materials selected from [TEL-1] to [TEL-7].

The IVL characteristics and T95 lifespan of Experimental Example 9 (EX9) and Experimental Example 10 (EX10) are evaluated.

TABLE 5

| | | | | IVL | T95 |
|---|---|---|---|---|---|
| | | | | @10 | @40° C., |
| | | | | mA/cm² | 40 mA/cm² |
| Experiment | | Material | | TTF ratio | Lifespan |
| 5 | Item | TEL | B EML | (%) | (%) |
| 1st B | EX9 | BH + BD (250 Å_2%) | | 31.2 | 100% |
| mono | EX10 | TEL | BH + BD | 33.9 | 127% |
| | | (50 Å) | (200 Å_2%) | | |

IVL characteristics were determined by calculating the TTF ratio at a current density of 10 mA/cm². T95 lifespan refers to time elapsed until the luminance reaches 95% of the initial luminance, and is obtained by measuring the elapsed time until the luminance reaches 95% of the initial luminance at a driving temperature of 40° C. and a current density of 40 mA/cm².

As shown in Table 5, it can be seen that both TTF efficiency and lifespan are improved in Experimental Example 10 (Ex10) including transfer layer an energy compared to Example 9 (EX9) including no energy transfer layer.

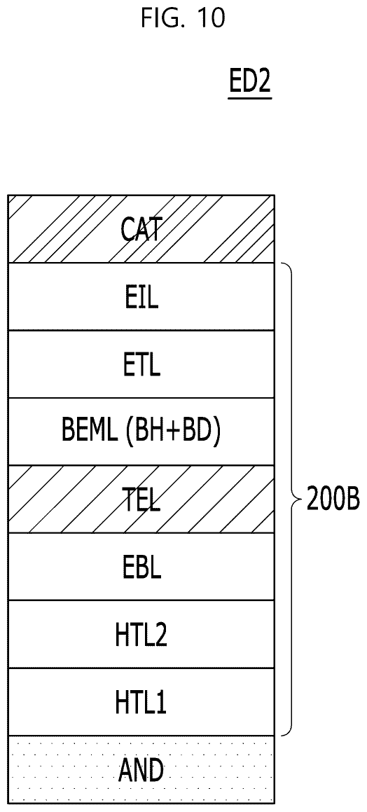

FIG. 10 is a cross-sectional view illustrating the light-emitting device used in Experiment 6.

As shown in FIG. 10, the light-emitting device used in Experiment 6 includes a stack configuration included in the second blue stack B2 of FIG. 8 between the first electrode AND and the second electrode CAT.

The configuration shown in FIG. 10 is the same as that in FIG. 1. For example, as shown in FIG. 10, the light-emitting device used in Experimental Example 6 includes a first electrode AND and a second electrode CAT facing each other, and a hole injection layer HIL, a hole transport layer HTL, an electron blocking layer EBL, an energy transfer layer TEL, a blue light-emitting layer B EML, an electron transport layer ETL, and an electron injection layer EIL disposed in this order between the first electrode AND and the second electrode CAT. This is the configuration of Experimental Example 4 (EX4) shown in Table 6. Here, the energy transfer layer TEL is formed to a thickness of 50 Å, and the blue light-emitting layer B EML is formed to a thickness of 250 Å.

Experimental Example 1 (EX1) includes a blue light-emitting layer B EML with a thickness of 300 Å, while not including an energy transfer layer between the electron blocking layer EBL and the blue light-emitting layer B EML.

TABLE 6

| | | | | IVL | T95 |
|---|---|---|---|---|---|
| | | | | @10 | @40° C., |
| | | | | mA/cm² | 40 mA/cm² |
| Experiment | | Material | | TTF ratio | Lifespan |
| 6 | Item | TEL | B EML | (%) | (%) |
| 3rd B | EX1 | BH + BD (300 Å_2%) | | 30.1 | 100% |
| mono | EX4 | TEL | BH + BD | 32.3 | 143% |
| | | (50 Å) | (250 Å_2%) | | |

IVL characteristics were determined by calculating the TTF ratio at a current density of 10 mA/cm². T95 lifespan refers to time elapsed until the luminance reaches 95% of the initial luminance, and is obtained by measuring the elapsed time until the luminance reaches 95% of the initial luminance at a driving temperature of 40° C. and a current density of 40 mA/cm².

It can be seen that both TTF efficiency and lifespan are improved in Experimental Example 4 (Ex4) including an energy transfer layer compared to Experimental Example 1 (EX1) including no energy transfer layer.

Hereinafter, the comparison in the effects of the structure (EX11) not including the energy transfer layer TEL and the structure (EX12) including the energy transfer layer TEL in both the first blue stack B1 and the second blue stack B2 of FIG. 8 will be described. Experimental Example 7 has the structure shown in FIG. 8.

The first blue stack B1 of Experimental Example 11 (EX11) in Experiment 7 has the configuration between the first and second electrodes among the configurations described in Experimental Example 9 (EX9) and Experimental Example 12 (EX12) and the first blue stack B1 includes the structure of the intermediate layer 200B between the first and second electrodes AND and CAT described in FIG. 9 and Experimental Example 10 (EX10).

The phosphorescent stacks PS of Experimental Example 11 (EX11) and Experimental Example 12 (EX12) include a hole transport layer, a red light-emitting layer, a yellow-green light-emitting layer, a green light-emitting layer, and an electron transport layer. The charge generation layer between stacks also has the same configuration.

The second blue stack B2 of Experimental Example 11 (EX11) of Experimental 7 has the configuration between the first and second electrodes among the configurations described in Experimental Example 1 (EX1), and the second blue stack B2 of Experimental Example 12 (EX12) has the structure of the intermediate layer 200B between the first and second electrodes AND and CAT described in FIG. 1 and Experimental Example 10 (EX10).

TABLE 7

| | | | | T95 |
|---|---|---|---|---|
| | | | | @40° C., |
| Experiment | | Material | | 40 mA/cm² |
| 7 | Item | B1 | B2 | Lifespan % |
| 3 stack | EX11 | Absence of TEL | Absence of TEL | 100% |
| | EX12 | Presence of TEL | Presence of TEL | 114% |

As shown in Table 7, in the configuration including multilayer stacks, Experimental Example 12 (EX12) including an energy transfer layer in each blue stack exhibits a 114% improvement in lifespan, compared to Experimental Example 11 (EX11) not including an energy transfer layer in each blue stack. The efficiency of Experimental Example 12 (EX12) in which an energy transfer layer was provided in each blue stack, compared to Experimental Example 11 (EX11) in which the energy transfer layer was not provided in each blue stack, is not shown in Table 7. However, as can be seen from Tables 5 and 6, the TTF efficiency increased in both the first and second blue stacks, and Experimental Example 12 (EX12) in which an energy transfer layer is provided in each blue stack, compared to Experimental Example 11 (EX11), exhibits an improvement in TTF efficiency, compared to a structure with an energy transfer layer in the stack.

Hereinafter, a light-emitting display device to which the light-emitting device of the present disclosure is applied will be described.

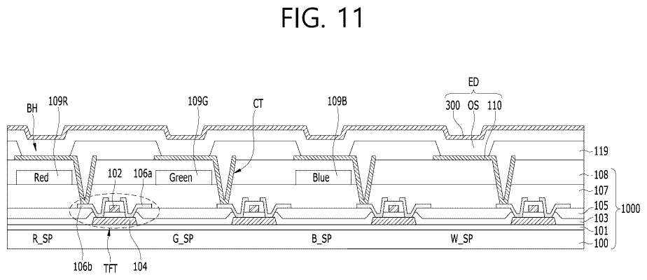

FIG. 11 is a cross-sectional view illustrating the light-emitting display device according to some embodiments of the present disclosure.

As shown in FIG. 11, the light-emitting display device according to some embodiments can emit white light through the first electrode 110 in the light-emitting area by commonly applying the light-emitting device to a plurality of sub-pixels (R_SP, G_SP, B_SP, W_SP).

As shown in FIG. 11, the light-emitting display of the present disclosure includes a substrate 100 having a plurality of subpixels R_SP, G_SP, B_SP, and W_SP, a light-emitting device (also referred to as “ED”) commonly provided on the substrate 100, a thin film transistor TFT provided in each of the subpixels R_SP, G_SP, B_SP, and W_SP and connected to the first electrode 110 of the light-emitting device ED, and a color filter layer 109R, 109G, or 109B provided below the first electrode 110 of at least one of the subpixels.

The example illustrated in FIG. 11 relates to a configuration including the white subpixel W_SP in the light-emitting display device, but the present disclosure is not limited thereto. A configuration in which the white subpixel W_SP is omitted and only the red, green, and blue subpixels R_SP, G_SP, and B_SP are provided is also possible. In some cases, a combination of a cyan subpixel, a magenta subpixel, and a yellow subpixel capable of forming white by replacing the red, green, and blue subpixels is possible.

The thin film transistor TFT includes, for example, a gate electrode 102, a semiconductor layer 104, and a source electrode 106a and a drain electrode 106b connected to respective sides of the semiconductor layer 104. In addition, a channel protection layer can be further provided in the portion where the channel of the semiconductor layer 104 is located in order to prevent direct connection between the source/drain electrodes 106a and 106b and the semiconductor layer 104. The thin film transistor TFT can include a buffer layer 101 on the substrate 100 and can be located on the buffer layer 101.

A gate insulating layer 103 is provided between the gate electrode 102 and the semiconductor layer 104.

The semiconductor layer 104 can be formed of, for example, an oxide semiconductor, amorphous silicon, polycrystalline silicon, or a combination thereof. For example, when the semiconductor layer 104 is an oxide semiconductor, the heating temperature required for forming the thin film transistor can be lowered, and thus the substrate 100 can be freely used and the semiconductor layer 104 is advantageously applied to a flexible display device.

A gate electrode 102 can be provided on the gate insulating film 103, and an interlayer insulating film 105 can be further provided between the gate electrode 102 and the source electrode 106a/drain electrode 106b.

In addition, the drain electrode 106b of the thin film transistor TFT can be connected to the first electrode 110 in a contact hole CT provided in the first and second passivation layers 107 and 108.

The first passivation layer 107 is provided to primarily protect the thin film transistor TFT, and color filters 109R, 109G, and 109B can be provided on the first passivation layer 107.

A second passivation layer 108 is provided on the first passivation layer 107 including the color filters 109R, 109G, and 109B.

As shown in FIG. 11, when the plurality of subpixels includes a red subpixel R_SP, a green subpixel G_SP, a blue subpixel B_SP, and a white subpixel W_SP, the color filter can include first to third color filters 109R, 109G, and 109B in each of the remaining subpixels R_SP, G_SP, and B_SP, excluding the white subpixel W_SP, and can allow the emitted white light to pass through the first electrode 110 for each wavelength. A second passivation layer 108 is formed under the first electrode 110 to cover the first to third color filters 109R, 109G, and 109B. The first electrode 110 is formed on the surface of the second passivation layer 108 excluding the contact hole CT, is connected to either the drain electrode 106b or the source electrode 106a of the thin film transistor TFT and receives an electrical signal from the thin film transistor TFT.

Here, a configuration including the substrate 100, the thin film transistor TFT, the color filters 109R, 109G, and 109B, and the first and second protective films 107 and 108 can be defined as the thin film transistor array substrate 1000.

The light-emitting device ED is formed on the thin film transistor array substrate 1000 including the bank 119 defining the light-emitting portion BH. The light-emitting device ED includes a transparent first electrode 110, a second electrode 300 of a reflective electrode facing the first electrode 110, and at least one of the first and second blue stacks B1 and B2 among the stacks separated through the first and second charge generation layers CGL1 and CGL2, including a hole transport layer HTL, an electron blocking layer EBL, and an energy transfer layer, a blue light-emitting layer B EML containing a host BH and a blue dopant BD, and an electron transport layer ETL, between the first and second electrodes 110 and 300, as described above.

The first electrode 110 is divided into respective subpixels, and the remaining layers of the light-emitting device ED excluding the first electrode 110 are integrally provided in the entire display area, regardless of respective subpixels.

Either the first electrode 110 or the second electrode 300 can be connected to a thin film transistor TFT.

When the light-emitting display device of the present disclosure described above includes a blue stack including an electron blocking layer, an energy transfer layer, and a light-emitting layer, the efficiency of blue, which has low efficiency compared to other colors, is improved, and in the light-emitting device (ED) that emits white light maintains the balance between the phosphorescent light-emitting stack and luminous efficacy, thereby greatly contributing to power consumption reduction.

Meanwhile, the light-emitting display device of FIG. 11 described above is shown as having a structure in which light is emitted downward, but the present disclosure is not limited thereto. For example, the first electrode 110 includes a reflective electrode, the second electrode 300 is a transparent electrode or a reflective and transmissive electrode, and the color filter is disposed on the second electrode 300 to form a light-emitting display device to apply the light-emitting device in a top-emission manner.

The main feature of the light-emitting display device of the present disclosure is including an energy transfer layer between the hole transport layer/electron blocking layer located and the blue light-emitting layer in the blue light-emitting stack. Thus the light-emitting display device of the present disclosure improves the TTF efficiency of the blue light-emitting layer and improves the lifespan of the light-emitting device.

The light-emitting device of the present disclosure and the light-emitting display device including the same are characterized by further including an energy transfer layer between the electron blocking layer and the light-emitting layer to transfer energy to the light-emitting layer, which contributes to improvement in TTF efficiency.

The energy transfer layer is formed of a material with excellent electron transport properties, and is formed of a material whose triplet energy level is higher than the triplet energy level of the light-emitting layer to ensure sufficient energy transfer to the light-emitting layer. Additionally, the energy transfer layer is preferably formed of a single material to ensure maximum efficiency in transferring energy to the light-emitting layer.

In addition, the thickness of the energy transfer layer is less than that of the light-emitting layer, thus providing sufficient delayed light emission due to increased TTF efficiency within the light-emitting layer.

The light-emitting device of the present disclosure causes energy transfer through the energy transfer layer, to allow excitons with a density increased through the energy transfer layer to participate in the delayed light emission of the light-emitting layer and thereby to prevent a decrease in lifespan caused by excitons or electrons accumulating at the interface with the electron blocking layer.

The light-emitting display device according to the present disclosure can improve the efficiency of the light-emitting layer, reduce the driving voltage, and thereby achieve environmental/social/governance (ESG) goals.

A light-emitting device according to some embodiments of the present disclosure can comprise a first electrode and a second electrode facing each other, an electron blocking layer, a light emitting layer, and an electron transport layer provided between the first electrode and the second electrode and an energy transfer layer provided between the electron blocking layer and the light emitting layer. The light emitting layer can comprise a host and a dopant, and a triplet energy level of the energy transfer layer can be higher than a triplet energy level of the host and is lower than a singlet energy level of the host.

In a light-emitting device according to some embodiments of the present disclosure, the triplet energy level of the energy transfer layer can be lower than a triplet energy level of the electron blocking layer.

In a light-emitting device according to some embodiments of the present disclosure, the dopant can be a boron-containing dopant that emits blue light.

A light-emitting device according to some embodiments of the present disclosure can further comprise a hole transport layer between the first electrode and the electron blocking layer.

In a light-emitting device according to some embodiments of the present disclosure, electron mobility of the energy transfer layer can be greater than electron mobility of the electron blocking layer and can be equal to or smaller than the electron mobility of the host.

In a light-emitting device according to some embodiments of the present disclosure, the singlet energy level of the host can be lower than twice the triplet energy level of the host, and twice the triplet energy level of the host can be lower than excitation energy level (Tn) of triplet-triplet fusion (TTF) of the host.

In a light-emitting device according to some embodiments of the present disclosure, a HOMO energy level of the energy transfer layer can be lower than a HOMO energy level of the electron blocking layer and can be equal to or higher than a HOMO energy level of the host. A LUMO energy level of the energy transfer layer can be lower than a LUMO energy level of the electron blocking layer and can be equal to or higher than a LUMO energy level of the host.

In a light-emitting device according to some embodiments of the present disclosure, the energy transfer layer can have a thickness of 0.1 to 0.5 times a thickness of the light emitting layer.

In a light-emitting device according to some embodiments of the present disclosure, the energy transfer layer can comprise electron transport material of a single type.

In a light-emitting device according to some embodiments of the present disclosure, the energy transfer layer can comprise pyrene, and any one of the pyrene and phenylene or naphthalene bonded to the pyrene can be substituted with deuterium.

In a light-emitting device according to some embodiments of the present disclosure, a first stack can comprise the electron blocking layer, the energy transfer layer, the light emitting layer, and the electron transport layer. The light-emitting device can further comprise a second stack having the same structure as the first stack between the first electrode and the second electrode, and the first stack and the second stack can be separated by a charge generation layer.

In a light-emitting device according to some embodiments of the present disclosure, a first stack can comprise the electron blocking layer, the energy transfer layer, the light emitting layer, and the electron transport layer. A dopant of the light-emitting layer can be a boron-containing dopant that emits blue light. The light-emitting device can further comprise a second stack disposed between the first electrode and the second electrode and including at least one phosphorescent layer that emits a different color light from the blue light. The first stack and the second stack can be separated by the charge generation layer.

A light-emitting device according to some embodiments of the present disclosure can further comprise a third stack having the same structure as the first stack between the first electrode and the second electrode.

In a light-emitting device according to some embodiments of the present disclosure, the second stack can comprise a hole transport common layer, a first phosphorescent light emitting layer, a second phosphorescent light emitting layer, and an electron transport common layer.

A light-emitting display device according to some embodiments of the present disclosure can comprise a substrate including a plurality of sub-pixels, a thin film transistor provided at each of the plurality of sub-pixels, a first electrode connected to the thin film transistor in at least one of the sub-pixels, a second electrode facing the first electrode, an electron blocking layer, a light emitting layer, and an electron transport layer provided between the first electrode and the second electrode and an energy transfer layer provided between the electron blocking layer and the light emitting layer. The light emitting layer can comprise a host and a dopant, and a triplet energy level of the energy transfer layer can be higher than a triplet energy level of the host and can be lower than a singlet energy level of the host.

The light-emitting device and the light-emitting display according to the present disclosure have the following effects.

The light-emitting device and the light-emitting display device including the same of the present disclosure further include an energy transfer layer between the electron blocking layer and the light-emitting layer to transfer energy to the light-emitting layer, improve the TTF efficiency within the light-emitting layer and improve the efficiency of the light-emitting layer.

The light-emitting display device according to the present disclosure increases the efficiency of generating triplet-triplet fusion (TTF) in the light-emitting layer through the Dexter energy transfer process of transferring excitons that are not used for direct light emission from the energy transfer layer to the host in the light-emitting layer, and through improved TTF efficiency, the exciton energy can be transferred back to the singlet energy level in the light-emitting layer to improve light-emitting efficiency.

The light-emitting display device according to the present disclosure maximizes light emission by excitons in the light-emitting layer, inhibits quenching of excitons not used for light emission, and prevents excitons or electrons from accumulating in layers adjacent to the light-emitting layer, thereby improving lifespan.

In addition, the light-emitting display device according to the present disclosure improves the efficiency of blue, which has low efficiency compared to other colors, and maintains the balance between phosphorescent stack and luminous efficiency in a white light-emitting device, thereby greatly contributing to reducing power consumption.

The light-emitting display device according to the present disclosure can improve the efficiency of the light-emitting layer, reduce the driving voltage, and thereby achieve environmental/social/governance (ESG) goals.

It will be apparent to those skilled in the art that various modifications and variations can be made in the disclosure without departing from the spirit or scope of the disclosure. Thus, it is intended that the disclosure covers such modifications and variations thereof, provided they fall within the scope of the appended claims and their equivalents.

What is claimed is:

1. A light-emitting device comprising:
a first electrode and a second electrode facing each other;
an electron blocking layer, a light emitting layer, and an electron transport layer provided between the first electrode and the second electrode; and
an energy transfer layer provided between the electron blocking layer and the light emitting layer,
wherein the light emitting layer comprises a host and a dopant, and
wherein a triplet energy level of the energy transfer layer is higher than a triplet energy level of the host and is lower than a singlet energy level of the host.

2. The light-emitting device according to claim 1, wherein the triplet energy level of the energy transfer layer is lower than a triplet energy level of the electron blocking layer.

3. The light-emitting device according to claim 1, wherein the dopant of the light emitting layer is a boron-containing dopant that emits blue light.

4. The light-emitting device according to claim 1, further comprising a hole transport layer between the first electrode and the electron blocking layer.

5. The light-emitting device according to claim 1, wherein an electron mobility of the energy transfer layer is greater than an electron mobility of the electron blocking layer and is equal to or smaller than the electron mobility of the host.

6. The light-emitting device according to claim 1, wherein the singlet energy level of the host is lower than twice the triplet energy level of the host, and
twice the triplet energy level of the host is lower than an excitation energy level (Tn) of a triplet-triplet fusion (TTF) of the host.

7. The light-emitting device according to claim 1, wherein a Highest Occupied Molecular Orbital (HOMO) energy level of the energy transfer layer is lower than a HOMO energy level of the electron blocking layer and is equal to or higher than a HOMO energy level of the host, and
wherein a Lowest Unoccupied Molecular Orbital (LUMO) energy level of the energy transfer layer is lower than a LUMO energy level of the electron blocking layer and is equal to or higher than a LUMO energy level of the host.

8. The light-emitting device according to claim 1, wherein the energy transfer layer has a thickness of 0.1 to 0.5 times a thickness of the light emitting layer.

9. The light-emitting device according to claim 1, wherein the energy transfer layer comprises an electron transport material of a single type.

10. The light-emitting device according to claim 1, wherein the energy transfer layer comprises pyrene.

11. The light-emitting device according to claim 10,
wherein the energy transfer layer further comprises at least one of phenylene, naphthalene and dibenzofuran.

12. The light-emitting device according to claim 11, wherein at least one hydrogen atom of the energy transfer layer is substituted with deuterium.

13. The light-emitting device according to claim 1, wherein a first stack comprises the electron blocking layer, the energy transfer layer, the light emitting layer, and the electron transport layer,
wherein the light-emitting device further comprises a second stack having the same structure as the first stack between the first electrode and the second electrode, and
wherein the first stack and the second stack are separated by a charge generation layer.

14. The light-emitting device according to claim 1, wherein a first stack comprises the electron blocking layer, the energy transfer layer, the light emitting layer, and the electron transport layer,
wherein a dopant of the light-emitting layer is a boron-containing dopant that emits blue light,
wherein the light-emitting device further comprises a second stack disposed between the first electrode and the second electrode and including at least one phosphorescent layer that emits
a different color light from the blue light, and wherein the first stack and the second stack are separated by the charge generation layer.

15. The light-emitting device according to claim 14, further comprising a third stack having a same structure as the first stack between the first electrode and the second electrode.

16. The light-emitting device according to claim 14, wherein the second stack comprises a hole transport common layer, a first phosphorescent light emitting layer, a second phosphorescent light emitting layer, and an electron transport common layer.

17. A light-emitting display device comprising:
a substrate including a plurality of sub-pixels;
a thin film transistor provided at each of the plurality of sub-pixels;
a first electrode connected to the thin film transistor in at least one of the sub-pixels;
a second electrode facing the first electrode;
an electron blocking layer, a light emitting layer, and an electron transport layer provided between the first electrode and the second electrode; and
an energy transfer layer provided between the electron blocking layer and the light emitting layer,
wherein the light emitting layer comprises a host and a dopant, and
wherein a triplet energy level of the energy transfer layer is higher than a triplet energy level of the host and is lower than a singlet energy level of the host.

18. The light-emitting display device according to claim 17, wherein the triplet energy level of the energy transfer layer is lower than a triplet energy level of the electron blocking layer.

19. The light-emitting display device according to claim 17, wherein the dopant of the light emitting layer is a boron-containing dopant that emits blue light.

20. The light-emitting display device according to claim 16, further comprising a hole transport layer between the first electrode and the electron blocking layer.

21. The light-emitting display device according to claim 17, wherein an electron mobility of the energy transfer layer is greater than an electron mobility of the electron blocking layer and is equal to or smaller than the electron mobility of the host.

22. The light-emitting display device according to claim 17, wherein the singlet energy level of the host is lower than twice the triplet energy level of the host, and
wherein twice the triplet energy level of the host is lower than an excitation energy level (Tn) of a triplet-triplet fusion (TTF) of the host.
